(19) United States
(12) Patent Application Publication
(10) Pub. No.: US 2025/0087544 A1
(43) Pub. Date: Mar. 13, 2025

(54) SEMICONDUCTOR PACKAGE WITH BINDING REINFORCEMENT LAYER

(71) Applicant: SAMSUNG ELECTRONICS CO., LTD., Suwon-si (KR)

(72) Inventor: Yuseon HEO, Suwon-si (KR)

(73) Assignee: SAMSUNG ELECTRONICS CO., LTD., Suwon-si (KR)

(21) Appl. No.: 18/367,801

(22) Filed: Sep. 13, 2023

(51) Int. Cl. H01L 23/31; H01L 23/00

(52) U.S. Cl. CPC H01L 23/315; H01L 24/32; H01L 24/48; H01L 24/73; H01L 2224/32225; H01L 2224/4807; H01L 2224/73265; H01L 2924/18301

(57) ABSTRACT

Provided is a semiconductor package including a first wiring structure including a plurality of first wiring patterns respectively including a plurality of first lower surface connection pads and a plurality of first upper surface connection pads, a second wiring structure including a plurality of second wiring patterns respectively including a plurality of second lower surface connection pads and a plurality of second upper surface connection pads, a semiconductor chip arranged between the first wiring structure and the second wiring structure, a plurality of connection structures connecting some of the plurality of first upper surface connection pads to the plurality of second lower surface connection pads, and arranged adjacent to the semiconductor chip, and a binding reinforcement layer on side surfaces of each of the plurality of connection structures and at least a portion of the semiconductor chip.

### CROSS-REFERENCE TO RELATED APPLICATION

This application claims priority to Korean Patent Application No. 10-2022-0126584, filed on Oct. 4, 2022 in the Korean Intellectual Property Office, the disclosure of which is incorporated by reference herein in its entirety.

### BACKGROUND

Embodiments of the present disclosure relate to a semiconductor package, and more particularly, to a fan out-type semiconductor package.

In response to the rapid development of the electronic industry and the needs of users, electronic devices are further miniaturized and multi-functionalized, and have a large capacity, and accordingly, highly integrated semiconductor chips are required.

Accordingly, for a highly integrated semiconductor chip with an increased number of connection terminals for input/output (I/O), a semiconductor package connection reliability has been devised. For example, a fan out-type semiconductor package with an increased gap between connection terminals for preventing interference between the connection terminals has been developed.

### SUMMARY

One or more embodiments provide a semiconductor package having an improved reliability.

A semiconductor package including a first wiring structure including a plurality of first wiring patterns respectively including a plurality of first lower surface connection pads and a plurality of first upper surface connection pads, and a first base insulating layer surrounding the plurality of first wiring patterns, a second wiring structure including a plurality of second wiring patterns respectively including a plurality of second lower surface connection pads and a plurality of second upper surface connection pads, and a second base insulating layer surrounding the plurality of second wiring patterns, a semiconductor chip between the first wiring structure and the second wiring structure, an encapsulation member filling a space between the first wiring structure and the second wiring structure and surrounding the semiconductor chip, a plurality of connection structures penetrating the encapsulation member and connecting some of the plurality of first upper surface connection pads to the plurality of second lower surface connection pads, the plurality of connection structures being adjacent to the semiconductor chip, and a binding reinforcement layer on side surfaces of each of the plurality of connection structures and at least a portion of side surfaces of the semiconductor chip.

A semiconductor package including a first wiring structure including a plurality of first rewiring patterns respectively including a plurality of first lower surface connection pads and a plurality of first upper surface connection pads, and a first rewiring insulating layer surrounding the plurality of first rewiring patterns, a second wiring structure including a plurality of second rewiring patterns respectively including a plurality of second lower surface connection pads and a plurality of second upper surface connection pads, and a second rewiring insulating layer surrounding the plurality of second rewiring patterns, a semiconductor chip between the first wiring structure and the second wiring structure, the semiconductor chip including a plurality of chip pads, a plurality of connection structures respectively connecting the plurality of first upper surface connection pads to the plurality of second lower surface connection pads, the plurality of connection structures being adjacent to the semiconductor chip, a binding reinforcement layer on side surfaces of each of the plurality of connection structures and at least a portion of the semiconductor chip, a plurality of chip connection members between some of the plurality of first upper surface connection pads and the plurality of chip pads, and an encapsulation member surrounding the plurality of connection structures and the semiconductor chip, filling a space between the first wiring structure and the second wiring structure, and being spaced apart from the semiconductor chip and each of the plurality of connection structures, the binding reinforcement layer being between the encapsulation member and each of the plurality of connection structures.

A semiconductor package including a first rewiring structure including a plurality of first rewiring patterns respectively including a plurality of first lower surface connection pads and a plurality of first upper surface connection pads, and a first rewiring insulating layer surrounding the plurality of first rewiring patterns, a semiconductor chip on the first rewiring structure and including a plurality of chip pads, a second rewiring structure including a plurality of second rewiring patterns on the semiconductor chip and the first rewiring structure, the plurality of second rewiring patterns respectively including a plurality of second lower surface connection pads and a plurality of second upper surface connection pads, and a second rewiring insulating layer surrounding the plurality of second rewiring patterns, a plurality of connection structures respectively connecting some of the plurality of first upper surface connection pads to the plurality of second lower surface connection pads, the plurality of connection structures being on the semiconductor chip, and a plurality of chip connection members between some of the plurality of first upper surface connection pads and the plurality of chip pads, the plurality of chip connection members respectively including a under bump metal (UBM) layer and a conductive cap on each of the plurality of chip pads, the conductive cap covering the UBM layer, an under-fill layer between the semiconductor chip and the first rewiring structure, the under-fill layer surrounding the plurality of chip connection members, a binding reinforcement layer on an upper surface of the first rewiring structure, side surfaces of each of the plurality of connection structures, side surfaces of the under-fill layer, at least a portion of side surfaces of the semiconductor chip, and an upper surface of the semiconductor chip, the binding reinforcement layer including an insulating material, and an encapsulation member filling a space between the first rewiring structure and the second rewiring structure, covering the plurality of connection structures and the semiconductor chip, and being spaced apart from the first rewiring structure, the semiconductor chip, and each of the plurality of connection structures, with the binding reinforcement layer between the encapsulation member and the first rewiring structure, the semiconductor chip, and each of the plurality of connection structures.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIGS. 2A, 2B, 2C, 2D, 2E, 2F, and 2G are cross-sectional views illustrating a method of manufacturing a semiconductor package, according to embodiments;

FIG. 3 is a cross-sectional view of a semiconductor package according to an embodiment;

FIGS. 4A, 4B, 4C, 4D, and 4E are cross-sectional views illustrating a method of manufacturing a semiconductor package, according to embodiments;

FIG. 5 is a cross-sectional view of a semiconductor package according to an embodiment;

FIGS. 6A, 6B, 6C, 6D, and 6E are cross-sectional views illustrating a method of manufacturing a semiconductor package, according to embodiments;

FIG. 7 is a cross-sectional view of a semiconductor package according to an embodiment;

FIGS. 8A, 8B, 8C, 8D, and 8E are enlarged cross-sectional views illustrating a method of manufacturing a semiconductor package, according to embodiments; and

FIGS. 9, 10, 11, and 12 are cross-sectional views of a semiconductor package according to embodiments.

### DETAILED DESCRIPTION OF THE EMBODIMENTS

Embodiments described herein are example embodiments, and thus, the disclosure is not limited thereto.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

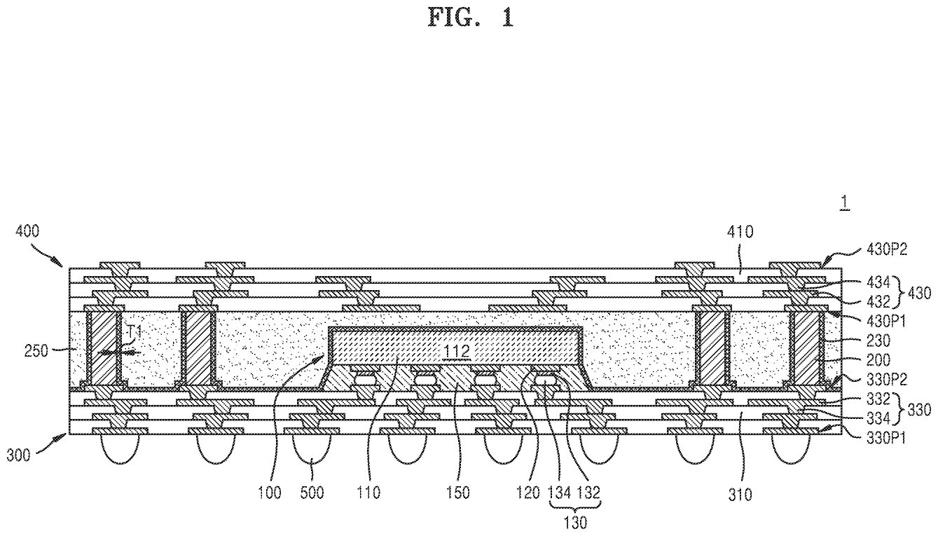

FIG. 1 is a cross-sectional view of a semiconductor package 1 according to an embodiment.

Referring to FIG. 1, the semiconductor package 1 may include a first wiring structure 300, a second wiring structure 400 on the first wiring structure 300, and at least one semiconductor chip 100 arranged between the first wiring structure 300 and the second wiring structure 400. In some embodiments, the semiconductor package 1 may include a lower package of a package-on-package (POP). The semiconductor package 1 may include a fan out-type semiconductor package, in which a horizontal width and a horizontal area of the first wiring structure 300 are respectively greater than a horizontal width and a horizontal area of at least one semiconductor chip 100. In some embodiments, the semiconductor package 1 may have a fan out-type wafer level package (FOWLP) or a fan out-type panel level package (FOPLP).

In some embodiments, at least one of the first wiring structure 300 and the second wiring structure 400 may be formed by using a rewiring process. The first wiring structure 300 and the second wiring structure 400 may be referred to as a first rewiring structure and a second rewiring structure, or may be referred to as a lower rewiring structure and an upper rewiring structure, respectively.

The first wiring structure 300 may include a first rewiring insulating layer 310 and a plurality of first rewiring patterns 330. The first rewiring insulating layers 310 may surround the plurality of first rewiring patterns 330. In some embodiments, the first wiring structure 300 may include a plurality of rewiring insulation layers 310, which are stacked on each other. The first rewiring insulating layer 310 may be formed by using, for example, photo imagable dielectric (PID) or photosensitive polyimide (PSPI). For example, the first wiring structure 300 may have a thickness of about 30 μm to about 50 μm.

The plurality of first rewiring patterns 330 may include a plurality of first rewiring line patterns 332 and a plurality of first rewiring vias 334. The plurality of first rewiring patterns 330 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof, but are not limited thereto. In some embodiments, the plurality of first rewiring patterns 330 may be formed by stacking a metal or an alloy of a metal on a seed layer including Cu, Ti, titanium nitride, or titanium tungsten.

The plurality of first rewiring line patterns 332 may be arranged on at least one of an upper surface and a lower surface of the first rewiring insulating layer 310. For example, when the first wiring structure 300 includes the plurality of first rewiring insulating layers 310, which are stacked on each other, the plurality of first rewiring line patterns 332 may be arranged on an upper surface of the first rewiring insulating layer 310 at the uppermost end, on a lower surface of the first rewiring insulating layer 310 at the lowermost end, and on at least a portion between two adjacent first rewiring insulating layers 310 among the plurality of first rewiring insulating layers 310.

The plurality of first rewiring vias 334 may penetrate at least one first rewiring insulating layer 310, and may be respectively in contact with and connected to some of the plurality of first rewiring line patterns 332. In some embodiment, the plurality of first rewiring vias 334 may have a tapered shape which widens and extends horizontally from the bottom to the top thereof. For example, the plurality of first rewiring vias 334 may have an increasing horizontal width toward at least one semiconductor chip 100.

In some embodiments, at least some of the plurality of first rewiring line patterns 332 may be integrally formed with some of the plurality of first rewiring vias 334. For example, the first rewiring line pattern 332 and the first rewiring via 334 in contact with a lower surface of the first rewiring line pattern 332 may be formed integrally. For example, each of the plurality of first rewiring vias 334 may have a decreasing horizontal width away from the first rewiring line pattern 332, which are integrated in one body.

Among the plurality of first rewiring patterns 330, some of the first rewiring patterns 330 arranged adjacent to a lower surface of the first wiring structure 300 may be referred to as a plurality of first lower surface connection pads 330P1, and some of the first rewiring patterns 330 arranged adjacent to an upper surface of the first wiring structure 300 may be referred to as a plurality of first upper surface connection pads 330P2. For example, the plurality of first lower surface connection pads 330P1 may be some of the plurality of first rewiring line patterns 332 adjacent to the lower surface of the first wiring structure 300, and the plurality of first upper surface connection pads 330P2 may be some of the plurality of first rewiring line patterns 332 adjacent to the upper surface of the first wiring structure 300.

A plurality of external connection terminals 500 may be respectively attached to the plurality of first lower surface connection pads 330P1. The plurality of external connection terminals 500 may electrically connect the semiconductor package 1 externally. In some embodiments, each of the plurality of external connection terminals 500 may include a bump, a solder ball, etc. For example, the external connection terminal 500 may have a height of about 100 μm to about 180 μm. A plurality of chip connection members 130 may be attached to some of the plurality of first upper surface connection pads 330P2, and a plurality of connection structures 200 may be attached to other of the plurality of first upper surface connection pads 330P2.

The plurality of first upper surface connection pads 330P2 may be arranged on the upper surface of the first rewiring insulating layer 310. For example, when the first wiring structure 300 includes the plurality of first rewiring insulating layers 310, which are stacked on each other, the plurality of first upper surface connection pads 330P2 may be arranged on the upper surface of the first rewiring insulating layer 310 at the uppermost end.

At least one semiconductor chip 100 may be attached on the first wiring structure 300. The semiconductor chip 100 may include a semiconductor substrate 110 having an active surface and an inactive surface, which are opposite to each other, a semiconductor device 112 formed on the active surface of the semiconductor substrate 110, and a plurality of chip pads 120 arranged on a first surface of the semiconductor chip 100. For example, the semiconductor chip 100 may have a thickness of about 70 μm to about 200 μm. In the present disclosure, the first surface of the semiconductor chip 100 and a second surface of the semiconductor chip 100 may be opposite to each other, and the second surface of the semiconductor chip 100 may be the inactive surface of the semiconductor substrate 110. Because the active surface of the semiconductor substrate 110 is close to the first surface of the semiconductor chip 100, an illustration of separating the active surface of the semiconductor substrate 110 from the first surface of the semiconductor chip 100 is omitted.

In some embodiments, the semiconductor chip 100 may have a face-down arrangement, in which the first surface of the semiconductor chip 100 faces the first wiring structure 300, and may be attached to the upper surface of the first wiring structure 300. In this case, the first surface of the semiconductor chip 100 may be referred to as a lower surface of the semiconductor chip 100, and the second surface of the semiconductor chip 100 may be referred to as an upper surface of the semiconductor chip 100. In the present disclosure, unless otherwise specified, an upper surface is referred to a surface facing an upper side in the drawing, and a lower surface is referred to a surface facing a lower side in the drawing.

The plurality of chip connection members 130 may be arranged between the plurality of chip pads 120 of the semiconductor chip 100 and some of the plurality of first upper surface connection pads 330P2 of the first wiring structure 300. For example, each of the plurality of chip connection members 130 may include a solder ball or a micro-bump. The semiconductor chip 100 may be electrically connected to the first rewiring pattern 330 of the first wiring structure 300 via the plurality of chip connection members 130. Each of the plurality of chip connection members 130 may include a under bump metal (UBM) layer 132 and a conductive cap 134 covering the UBM layer 132, which are arranged under each of the plurality of chip pads 120. For example, each of the plurality of chip connection members 130 may have a height of about 30 μm to about 40 μm. Each of the plurality of chip connection members 130 may include a conductive material, for example, Cu, Al, silver (Ag), Sn, gold (Au), or solder, but is not limited thereto.

The semiconductor substrate 110 may include, for example, a semiconductor material, such as silicon (Si) and germanium (Ge). According to another embodiment, the semiconductor substrate 110 may include a compound semiconductor material, such as silicon carbide (SiC), gallium arsenide (GaAs), indium arsenide (InAs), and indium phosphate (InP). The semiconductor substrate 110 may include a conductive region, for example, a well doped with impurities. The semiconductor substrate 110 may have various element isolation structures such as a shallow trench isolation (STI) structure.

The semiconductor substrate 110 may include the semiconductor device 112, including a plurality of individual devices of various types, on the active surface of the semiconductor substrate 110. The plurality of individual devices may include various microelectronic devices, for example, a metal-oxide-semiconductor field effect transistor (MOSFET) such as a complementary metal-insulator-semiconductor (CMOS) transistor, system large scale integration (LSI), an active device, a passive device, etc. The plurality of individual devices may be electrically connected to the conductive region of the semiconductor substrate 110. The semiconductor device 112 may further include a conductive wiring or a conductive plug electrically connecting at least two of the plurality of individual devices to each other, or the plurality of individual devices to the conductive region of the semiconductor substrate 110. In addition, each of the plurality of individual devices may be electrically isolated from another adjacent individual devices by an insulating layer.

In some embodiments, the semiconductor chip 100 may include a logic device. For example, the semiconductor chip 100 may include a central processing unit (CPU) chip, a graphics processing unit (GPU) chip, or an application processor (AP) chip. In some other embodiments, when the semiconductor package 1 includes a plurality of semiconductor chips 100, at least one of the plurality of semiconductor chips 100 may include a CPU chip, a GPU chip, or an AP chip, and at least one another thereof may include a memory semiconductor chip including a memory device. For example, the memory device may include, for example, a non-volatile memory device, such as a flash memory, phase change random access memory (RAM) (PRAM), magnetic RAM (MRAM), ferroelectric RAM (FeRAM), and resistive RAM (RRAM). The flash memory may include, for example, an NAND flash memory, or a V-NAND flash memory. In some embodiments, the memory device may include a volatile memory device, such as dynamic RAM (DRAM) and static RAM (SRAM).

The second wiring structure 400 may include a second rewiring insulating layer 410 and a plurality of second rewiring patterns 430. The second rewiring insulating layer 410 may surround the plurality of second rewiring patterns 430. The second rewiring insulating layer 410 may be formed from, for example, PID or a photosensitive polyimide.

In some embodiments, the thickness of the second wiring structure 400 may be less than the thickness of the first wiring structure 300. For example, the second wiring structure 400 may have the thickness of about 20 μm to about 40 μm. In some embodiments, the second wiring structure 400 may include a plurality of second rewiring insulating layers 410, which are stacked. The plurality of second rewiring patterns 430 may include a plurality of second rewiring line patterns 432, and a plurality of second rewiring vias 434. The plurality of second rewiring patterns 430 may include a metal or an alloy of metal, but are not limited thereto. In some embodiments, the plurality of second rewiring patterns 430 may be formed by stacking a metal or an alloy of a metal on the seed layer.

The plurality of second rewiring line patterns 432 may be arranged on at least one of an upper surface and a lower surface of the second rewiring insulating layer 410. For example, when the second wiring structure 400 includes the plurality of second rewiring insulating layers 410, which are stacked on each other, the plurality of second rewiring line patterns 432 may be arranged on an upper surface of the second rewiring insulating layer 410 at the uppermost end, on a lower surface of the second rewiring insulating layer 410 at the lowermost end, and on at least a portion between two adjacent second rewiring insulating layers 410 among the plurality of second rewiring insulating layers 410.

Among the plurality of second rewiring patterns 430, some second rewiring patterns 430 arranged adjacent to a lower surface of the second wiring structure 400 may be referred to as a plurality of second lower surface connection pads 430P1, and the other second rewiring patterns 430 arranged adjacent to an upper surface of the second wiring structure 400 may be referred to as a plurality of second upper surface connection pads 430P2. For example, the plurality of second lower surface connection pads 430P1 may be arranged adjacent to the lower surface of the second wiring structure 400 among the plurality of second rewiring line patterns 432, and the plurality of second upper surface connection pads 430P2 may be arranged adjacent to the upper surface of the second wiring structure 400 among the plurality of second rewiring line patterns 432. In some other embodiments, the plurality of second lower surface connection pads 430P1 may include some of the plurality of second rewiring vias 434 arranged adjacent to the lower surface of the second wiring structure 400.

In some embodiments, when the semiconductor package 1 includes a lower package of a PoP, an upper package thereof may be connected to a plurality of second upper surface connection pads 430P2. For example, a plurality of package connection terminals may be arranged between the upper package and the plurality of second upper surface connection pads 430P2. In some embodiments, each of the plurality of package connection terminals may include a bump, a solder ball, etc. The upper package may include an auxiliary semiconductor chip. The auxiliary semiconductor chip may include a memory semiconductor chip. For example, the auxiliary semiconductor chip may include a DRAM chip, an SRAM chip, a flash memory chip, an EEPROM chip, a PRAM chip, an MRAM chip, or an RRAM chip. The plurality of connection structure 200 may be respectively attached to the plurality of second lower surface connection pads 430P1.

The plurality of second lower surface connection pads 430P1 may be arranged on the lower surface of the second rewiring insulating layer 410. For example, when the second wiring structure 400 includes the plurality of second rewiring insulating layers 410, which are stacked on each other, the plurality of second lower surface connection pads 430P1 may be arranged on the lower surface of the lowermost second rewiring insulating layer 410.

The plurality of second upper surface connection pads 430P2 may be arranged on the upper surface of the second rewiring insulating layer 410. For example, when the second wiring structure 400 includes the plurality of second rewiring insulating layers 410, which are stacked on each other, the plurality of second upper surface connection pads 430P2 may be arranged on the upper surface of the uppermost second rewiring insulating layer 410. The plurality of second upper surface connection pads 430P2 may protrude from the upper surface of the second rewiring insulating layer 410 in a vertical direction, that is, in a direction opposite to the semiconductor chip 100 and the first wiring structure 300. For example, when the second wiring structure 400 includes the plurality of second rewiring insulating layers 410, which are stacked on each other, the plurality of second upper surface connection pads 430P2 may protrude from the upper surface of the second rewiring insulating layer 410 at the uppermost end in a vertical direction away from the semiconductor chip 100 and the first wiring structure 300. An upper surface and at least a portion of the side surfaces of each of the plurality of second upper surface connection pads 430P2 may not be in contact with the second rewiring insulating layer 410.

The plurality of second rewiring vias 434 may penetrate at least one second rewiring insulating layer 410, and may be respectively in contact with and connected to some of the plurality of second rewiring line patterns 432. In some embodiments, at least some of the plurality of second rewiring line patterns 432 may be formed integrally with some of the plurality of second rewiring vias 434. For example, the second rewiring line pattern 432 and the second rewiring via 434 in contact with the lower surface of the second rewiring line pattern 432 may be formed together in one body.

In some embodiments, the plurality of second rewiring vias 434 may have a tapered shape which widens and extends horizontally from the bottom to the top thereof. For example, the plurality of second rewiring vias 434 may have a decreasing horizontal width toward at least one semiconductor chip 100. The plurality of first rewiring vias 334 and the plurality of second rewiring vias 434 may extend in the same direction, and may each have an increasing horizontal width or a decreasing horizontal width. For example, the plurality of first rewiring vias 334 and the plurality of second rewiring vias 434 may have tapered shapes which extend in a direction from the first wiring structure 300 toward the second wiring structure 400 and have increasing horizontal widths, or extend in a direction from the second wiring structure 400 toward the first wiring structure 300 and have decreasing horizontal widths.

The first rewiring insulating layer 310, the first rewiring pattern 330, the first rewiring line pattern 332, and the first rewiring via 334 may be referred to as a first base insulating layer, a first wiring pattern, a first wiring line pattern, and a first wiring via, respectively, and the second rewiring insulating layer 410, the second rewiring pattern 430, the second rewiring line pattern 432, and the second rewiring via 434 may be referred to as a second base insulation layer, a second wiring pattern, a second rewiring line pattern, and a second rewiring via, respectively.

An encapsulation member 250 may surround the semiconductor chip 100 on the upper surface of the first wiring structure 300. The encapsulation member 250 may fill a space between the first wiring structure 300 and the second wiring structure 400. For example, the encapsulation member 250 may have a thickness of about 150 μm to about 300 μm. For example, the encapsulation member 250 may include a molding member including an epoxy mold compound (EMC). The encapsulation member 250 may contain a filler. For example, the filler may include a ceramic-based material having non-conductive insulating properties. In some embodiments, the filler may include at least one of aluminum nitride (AlN), boron nitride (BN), aluminum oxide (Al₂O₃), silicon carbide (SiC), and magnesium oxide (MgO). For example, the filler may include a silica filler or an alumina filler. For example, the encapsulation member 250 may include an epoxy-based material containing the filler. An average diameter of the filler contained in the encapsulation member 250 may be about 3 μm to about 50 μm. The ratio of the filler contained in the encapsulation member 250 may be about 60 wt % to about 90 wt %.

In some embodiment, an under-fill layer 150 surrounding the plurality of chip connection members 130 may be between the semiconductor chip 100 and the first wiring structure 300. In some embodiments, the under-fill layer 150 may fill a space between at least one semiconductor chip 100 and the first wiring structure 300, and cover a portion of lower sides of side surfaces of at least one semiconductor chip 100. The under-fill layer 150 may include, for example, an epoxy resin formed by a capillary under-fill method. In some embodiments, the under-fill layer 150 may include a non-conductive film (NCF).

In some embodiments, side surfaces of the first wiring structure 300, side surfaces of the encapsulation member 250, and side surfaces of the second wiring structure 400 may be aligned with each other in the vertical direction. For example, one side surface of the first wiring structure 300, one side surface of the encapsulation member 250, and one side surface of the second wiring structure 400, which correspond to each other, may be coplanar.

The plurality of connection structures 200 may penetrate the encapsulation member 250, and electrically connect the first wiring structure 300 to the second wiring structure 400. The encapsulation member 250 may surround the plurality of connection structures 200.

The plurality of connection structures 200 may be arranged between the first wiring structure 300 and the second wiring structure 400 so that the plurality of connection structures 200 are spaced apart from at least one semiconductor chip 100 in a horizontal direction. For example, the plurality of connection structures 200 may be spaced apart from at least one semiconductor chip 100 in the horizontal direction, and arranged around at least one semiconductor chip 100. The plurality of connection structures 200 may be between the plurality of first upper surface connection pads 330P2 and the plurality of second lower surface connection pads 430P1. Lower surfaces of the plurality of connection structures 200 may be in contact with the plurality of first upper surface connection pads 330P2 of the first wiring structure 300 and electrically connected to the plurality of first rewiring patterns 330, respectively, and upper surfaces of the plurality of connection structures 200 may be in contact with the plurality of second lower surface connection pads 430P1 and electrically connected to the plurality of second rewiring patterns 430, respectively. For example, the height of each of the plurality of connection structures 200 may be about 150 μm to about 300 μm, and a horizontal width of each of the plurality of connection structures 200 may be about 120 μm to about 200 μm. An aspect ratio of each of a plurality of connection structures 200, that is, a ratio of a height over a horizontal width, may be greater than about 1. In some embodiments, each of the plurality of connection structures 200 may include a conductive post including Cu or a Cu alloy.

The lower surface of each of the plurality of connection structures 200 may be in contact with an upper surface of the first upper surface connection pad 330P2. The upper surface of each of the plurality of connection structures 200 may be in contact with a lower surface of the second lower surface connection pad 430P1. In some embodiments, a horizontal width and a horizontal area of the first upper surface connection pad 330P2 in contact with the connection structure 200 may be greater than a horizontal width and a horizontal area of the connection structure 200. In some embodiments, the horizontal width and a horizontal area of the second lower surface connection pad 430P1 in contact with the connection structure 200 may be greater than the horizontal width and the horizontal area of the connection structure 200. For example, the lower surface of the connection structure 200 may be entirely in contact with the upper surface of the first upper surface connection pad 330P2, but a portion of the upper surface of the first upper surface connection pad 330P2 may not be in contact with the plurality of connection structures 200. For example, the upper surface of the connection structure 200 may be entirely in contact with the lower surface of the second lower surface connection pad 430P1, but a portion of the lower surface of the second lower surface connection pad 430P1 may not be in contact with the plurality of connection structures 200.

The plurality of first upper surface connection pads 330P2 may protrude from the upper surface of the first rewiring insulating layer 310 in the vertical direction toward the semiconductor chip 100 and the second wiring structure 400. For example, when the first wiring structure 300 includes the plurality of first rewiring insulating layers 310, which are stacked on each other, the plurality of first upper surface connection pads 330P2 may protrude from the upper surface of the first rewiring insulating layer 310 at the uppermost end in the vertical direction toward the semiconductor chip 100 and the second wiring structure 400. The upper surface and at least a portion of the side surfaces of each of the plurality of first upper surface connection pads 330P2 may not be in contact with the first rewiring insulating layer 310. The encapsulation member 250 may cover the side surfaces and at least a portion of the upper surface of each of the plurality of first upper surface connection pads 330P2. The plurality of first lower surface connection pads 330P1 may not protrude in the vertical direction from the lower surface of the first rewiring insulating layer 310 at the lowermost end. In some embodiments, the lower surface of the plurality of first lower surface connection pads 330P1 and the lower surface of the first rewiring insulating layer 310 may be coplanar.

The plurality of second lower surface connection pads 430P1 may not protrude in the vertical direction from the lower surface of the second rewiring insulating layer 410 at the lowermost end. In some embodiments, the lower surface of the plurality of second lower surface connection pads 430P1 and the lower surface of the second rewiring insulating layer 410 may be coplanar. The encapsulation member 250 may cover a portion of the lower surface of each of the plurality of second lower surface connection pads 430P1. The encapsulation member 250 may be in direct contact with a portion of the lower surface of each of the plurality of second lower surface connection pads 430P1, and the lower surface of the second rewiring insulating layer 410 at the lowermost end.

A binding reinforcement layer 230 may cover the first wiring structure 300, to which the plurality of connection structures 200 and at least one semiconductor chip 100 are attached. The binding reinforcement layer 230 may conformally cover, with a first thickness T1 the plurality of connection structure 200 and the first wiring structure 300, to which at least one semiconductor chip 100 is attached. For example, the first thickness T1 may be about 100 nm to about 3 μm. The binding reinforcement layer 230 may include an insulating material. In some embodiments, the binding reinforcement layer 230 may include silicon oxynitride (SiON).

The first wiring structure 300, to which the plurality of connection structures 200 and at least one semiconductor chip 100 are attached, may be spaced apart from the encapsulation member 250 with the binding reinforcement layer 230 therebetween. For example, the binding reinforcement layer 230 may be arranged between the first wiring structure 300, to which the plurality of connection structures 200 and at least one semiconductor chip 100 are attached, and the encapsulation member 250, and may extend along a space therebetween.

The binding reinforcement layer 230 may cover the side surfaces of each of the plurality of connection structures 200. For example, the binding reinforcement layer 230 may be arranged between the side surfaces of each of the plurality of connection structures 200 and the encapsulation member 250, and the encapsulation member 250 may be in contact with the binding reinforcement layer 230, but may not be in contact with the plurality of connection structures 200. The plurality of connection structures 200 and the encapsulation member 250 may be spaced apart from each other with the binding reinforcement layer 230 therebetween. One of the opposite sides of the binding reinforcement layer 230 may be in direct contact with the connection structure 200, and the other of the opposite sides of the binding reinforcement layer 230 may be in direct contact with the encapsulation member 250. The binding reinforcement layer 230 may not cover the upper surface of each of the plurality of connection structures 200 which is in contact with the second lower surface connection pad 430P1. Because the lower surface of each of the plurality of connection structures 200 is in contact with the first upper surface connection pad 330P2, the binding reinforcement layer 230 may not cover the lower surface of each of the plurality of connection structures 200.

The binding reinforcement layer 230 may surround at least one semiconductor chip 100. For example, the binding reinforcement layer 230 may cover the upper surface of at least one semiconductor chip 100, and may cover at least a portion of the side surfaces of at least one semiconductor chip 100. For example, the binding reinforcement layer 230 may be arranged between at least one semiconductor chip 100 and the encapsulation member 250, the encapsulation member 250 may be in contact with the binding reinforcement layer 230, but may not contact at least one semiconductor chip 100. At least one semiconductor chip 100 and the encapsulation member 250 may be spaced apart from each other with the binding reinforcement layer 230 therebetween. One of the opposite sides of the binding reinforcement layer 230 may be in direct contact with at least one semiconductor chip 100, and the other of the opposite sides of the binding reinforcement layer 230 may be in direct contact with the encapsulation member 250.

In some embodiments, when the under-fill layer 150 is arranged between the semiconductor chip 100 and the first wiring structure 300, the binding reinforcement layer 230 may cover the under-fill layer 150. For example, the binding reinforcement layer 230 may be arranged between the under-fill layer 150 and the encapsulation member 250, and the encapsulation member 250 may contact the binding reinforcement layer 230, but may not contact the under-fill layer 150. The under-fill layer 150 and the encapsulation member 250 may be spaced apart from each other with the binding reinforcement layer 230 therebetween. One of the opposite sides of the binding reinforcement layer 230 may be in direct contact with the under-fill layer 150, and the other of the opposite sides of the binding reinforcement layer 230 may be in direct contact with the encapsulation member 250.

The binding reinforcement layer 230 may cover the upper surface of the first wiring structure 300. For example, the binding reinforcement layer 230 may be arranged between the upper surface of the first wiring structure 300 and the encapsulation member 250, the encapsulation member 250 may contact the binding reinforcement layer 230, but may not contact the first wiring structure 300. The first wiring structure 300 and the encapsulation member 250 may be spaced apart from each other with the binding reinforcement layer 230 therebetween. One of the opposite sides of the binding reinforcement layer 230 may be in direct contact with the upper surface of the first wiring structure 300, and the other of the opposite sides of the binding reinforcement layer 230 may be in direct contact with the encapsulation member 250. For example, the binding reinforcement layer 230 may be in contact with the upper surface of the first rewiring insulating layer 310 at the uppermost end, and a portion of the upper surface and a portion of the side surfaces of the plurality of first upper surface connection pads 330P2.

The binding reinforcement layer 230 may extend along and cover the first rewiring insulating layer 310 on the upper surface of the first wiring structure 300, a portion of the side surfaces of the first upper surface connection pad 330P2 protruding in the vertical direction from the upper surface of the first rewiring insulating layer 310, and a portion of the upper surface of the first upper surface connection pad 330P2, the portion of the upper surface being not in contact with the connection structures 200.

The binding reinforcement layer 230 may extend along and conformally cover the upper surface of the first wiring structure 300, the side surfaces of the under-fill layer 150, at least a portion of the side surfaces of at least one semiconductor chip 100, and the upper surface of at least one semiconductor chip 100. When covering a lower portion of the side surfaces of at least one semiconductor chip 100 of the under-fill layer 150, the binding reinforcement layer 230 may cover all remaining portions of the side surfaces of at least one semiconductor chip 100, which the under-fill layer 150 does not cover. When the side surfaces of at least one semiconductor chip 100 are not covered by the under-fill layer 150, the binding reinforcement layer 230 may cover all of the side surfaces of at least one semiconductor chip 100.

The binding reinforcement layer 230 may be in contact and combined with the semiconductor chip 100, the under-fill layer 150, the first rewiring insulating layer 310, the first upper surface connection pad 330P2, the plurality of connection structures 200, and the encapsulation member 250. For example, the binding reinforcement layer 230 may be combined in hydrogen binding and sharing binding with the semiconductor chip 100, the under-fill layer 150, the first rewiring insulating layer 310, the first upper surface connection pad 330P2, the plurality of connection structures 200, and the encapsulation member 250, and the adhesion of the binding reinforcement layer 230 may be improved. Accordingly, components adjacent to the encapsulation member 250, for example, the semiconductor chip 100, the under-fill layer 150, the first rewiring insulating layer 310, the first upper surface connection pad 330P2, the plurality of connection structures 200, and the encapsulation member 250 may have an improved adhesion with the encapsulation member 250 by using the binding reinforcement layer 230. Accordingly, occurrence of delamination between the encapsulation member 250 and components adjacent to the encapsulation member 250 may be prevented.

The binding reinforcement layer 230 may not cover the upper surface of the encapsulation member 250. The upper surface of the encapsulation member 250 may be in contact with the lower surface of the second wiring structure 400. For example, the encapsulation member 250 may be in contact with the second rewiring insulating layer 410 on the lower surface of the second wiring structure 400, lower surfaces of sine if the second lower surface connection pads 430P1, and a portion of the lower surface of the second lower surface connection pad 430P1 not in contact with the connection structure 200.

In the semiconductor package 1 according to the present disclosure, the binding reinforcement layer 230 may be arranged between each of the components adjacent to the encapsulation member 250, for example, between each of the semiconductor chip 100, the under-fill layer 150, the first rewiring insulating layer 310, the first upper surface connection pad 330P2, and the plurality of connection structures 200, and the encapsulation member 250. Accordingly, because delamination, in which there are moisture causing reliability deterioration, residual ions, or the like, does not occur inside the semiconductor package 1 according to the embodiments of the present disclosure, the reliability of the semiconductor package 1 may be improved.

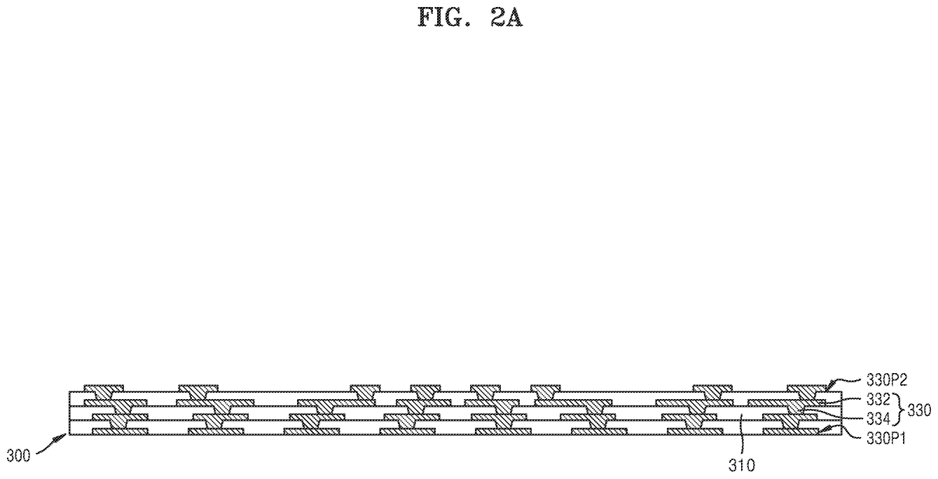

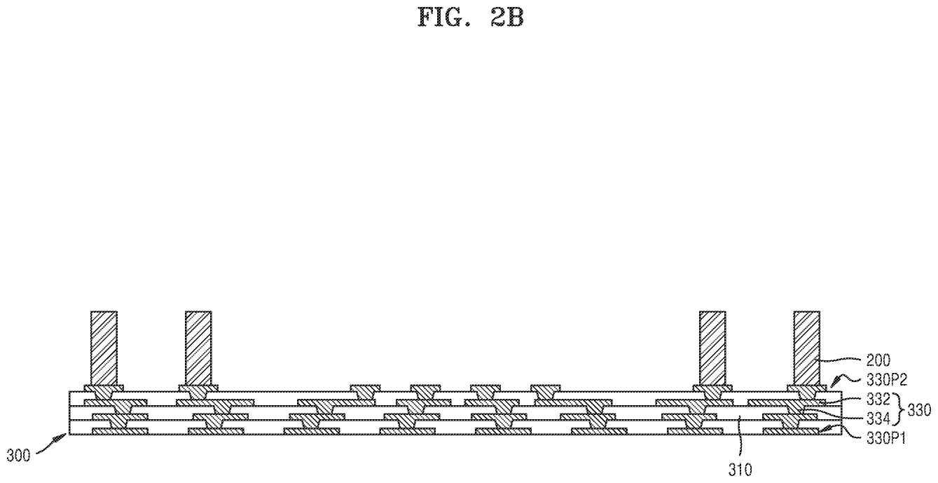

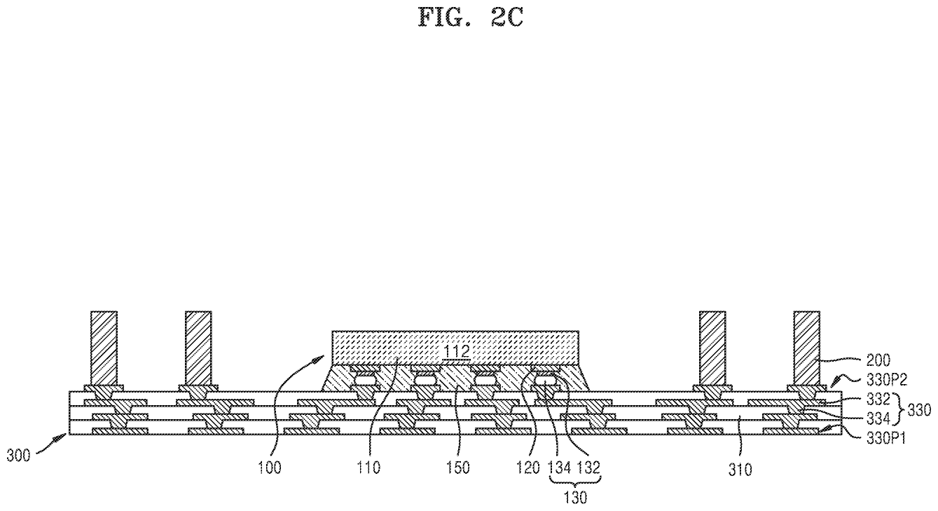

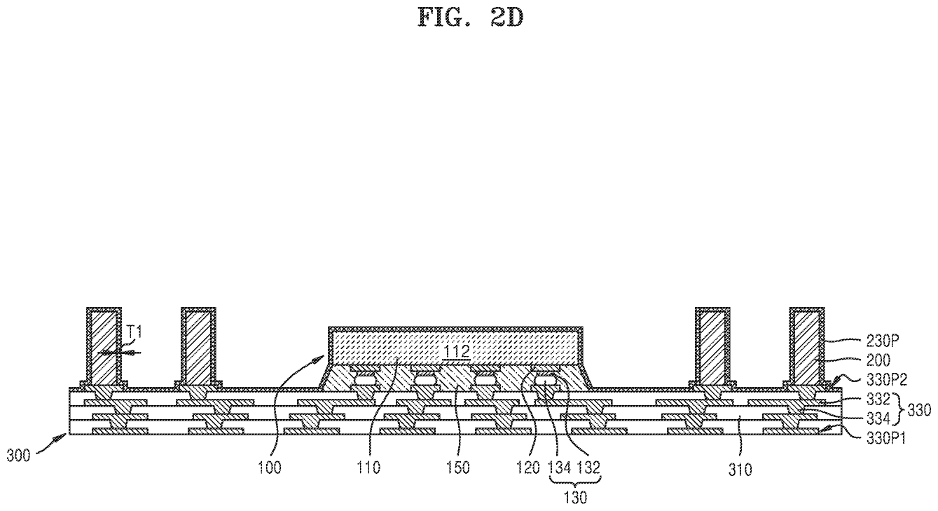

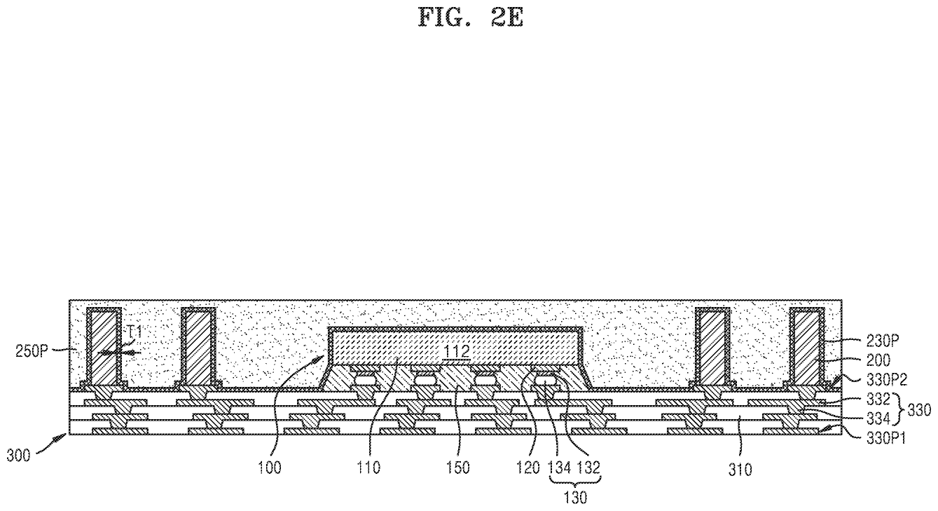

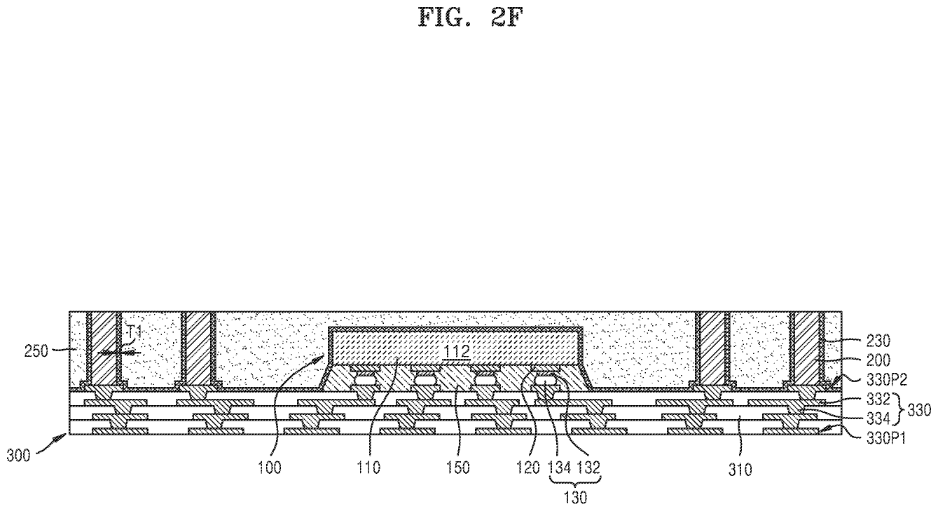

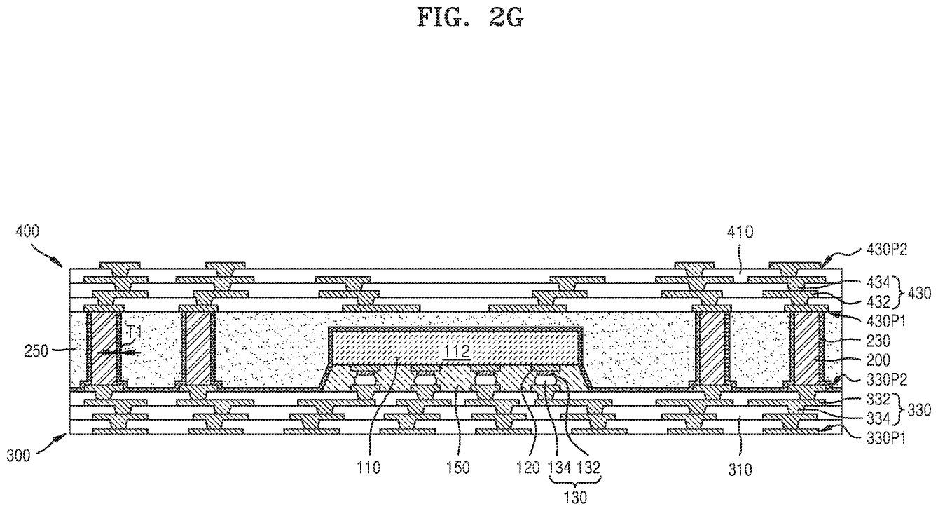

FIGS. 2A through 2G are cross-sectional views illustrating a method of manufacturing the semiconductor package 1, according to embodiments. FIGS. 2A through 2G are cross-sectional views illustrating a method of manufacturing the semiconductor package 1 illustrated in FIG. 1, and duplicate descriptions thereof may be omitted.

Referring to FIG. 2A, the first wiring structure 300 including the first rewiring insulating layer 310, and the plurality of first rewiring patterns 330 including the plurality of first rewiring line patterns 332 and the plurality of first rewiring vias 334 may be formed on a support substrate. The support substrate may include a semiconductor substrate, a glass substrate, a ceramic substrate, or a plastic substrate. In some embodiments, after a release film is attached to the support substrate, the first wiring structure 300 may be formed.

The first rewiring line patterns 332 may be formed on the support substrate. The first rewiring line patterns 332 formed on the support substrate may include a plurality of first lower surface connection pads 330P1. Thereafter, after a first preliminary rewiring insulating layer covering the first rewiring line patterns 332 on the support substrate is formed, by removing a portion of the first preliminary rewiring insulating layer by using an exposure process and a development process, the first rewiring insulating layer 310 including a plurality of first via holes may be formed. The plurality of first via holes may be formed such that a horizontal width thereof decreases from an upper surface to a lower surface of the first rewiring insulating layer 310. In some embodiments, the lower surface of the plurality of first lower surface connection pads 330P1 and the lower surface of the first rewiring insulating layer 310 at the lowermost end may be coplanar.

After a first rewiring conductive layer is formed on the first rewiring insulating layer 310, the first rewiring conductive layer may be patterned, and the first rewiring patterns 330 including first rewiring line patterns 332 and the first rewiring vias 334 may be further formed. The first rewiring vias 334 may include portions filling the plurality of first via holes among the first rewiring patterns 330, and the first rewiring line patterns 332 may include portions above the upper surface of the first rewiring insulating layer 310 among the first rewiring patterns 330.

The first rewiring vias 334 may be formed such that a horizontal width thereof decreases from the upper surface to the lower surface of the first rewiring insulating layer 310. Because the first rewiring patterns 330 including the first rewiring line patterns 332 and the first rewiring vias 334 are formed by patterning the first rewiring conductive layer, at least some of the first rewiring line patterns 332 formed on the first rewiring insulating layer 310 including the plurality of first via holes may form one body with at least some of the first rewiring vias 334.

Thereafter, the first rewiring insulating layer 310 and the first rewiring patterns 330 may be repeatedly formed, to form the first wiring structure 300. The first rewiring line patterns 332 formed to be arranged on the upper surface of the first wiring structure 300 may include a plurality of first upper surface connection pads 330P2. In some embodiments, the plurality of first upper surface connection pads 330P2 may be formed to protrude from the upper surface of the first rewiring insulating layer 310 at the uppermost end. In some embodiments, when the first wiring structure 300 is formed to include a plurality of first rewiring insulating layers 310, which are stacked on each other, the plurality of first upper surface connection pads 330P2 may include the first rewiring line patterns 332 formed to be arranged on the upper surface of the first rewiring insulating layer 310 at the uppermost end.

Referring to FIG. 2B, the plurality of connection structures 200 may be formed on some of the plurality of first upper surface connection pads 330P2. In some embodiments, after a mask pattern exposing a portion of each of the plurality of first upper surface connection pads 330P2 is formed on the first wiring structure 300, by performing a plating process on a portion of each of the first upper surface connection pad 330P2, which is exposed, the plurality of connection structures 200 may be formed. After the plurality of connection structures 200 are formed, the mask pattern may be removed.

Referring to FIG. 2C, at least one semiconductor chip 100 including the plurality of chip pads 120 may be attached onto the first wiring structure 300. The semiconductor chip 100 may be attached onto the first wiring structure 300 so that the plurality of chip connection members 130 are arranged between the plurality of chip pads 120 and some of the plurality of first upper surface connection pads 330P2 of the first wiring structure 300. The semiconductor chip 100 may be attached onto the first wiring structure 300 to be spaced apart from the plurality of connection structures 200 in the horizontal direction. In some embodiments, after each of the plurality of chip connection members 130 including the UBM layer 132 and the conductive cap 134 covering the UBM layer 132 is formed on the plurality of chip pads 120 of at least one semiconductor chip 100, at least one semiconductor chip 100, in which the plurality of chip connection members 130 are formed, may be attached onto the first wiring structure 300.

The under-fill layer 150 may be formed to fill a space between at least one semiconductor chip 100 and the first wiring structure 300. The under-fill layer 150 may be formed to surround the plurality of chip connection members 130. In some embodiments, the under-fill layer 150 may be formed to fill a space between at least one semiconductor chip 100 and the first wiring structure 300, and to cover portions of lower sides of side surfaces of at least one semiconductor chip 100.

Referring to FIG. 2D, a preliminary binding reinforcement layer 230P may be formed on the first wiring structure 300, to which the plurality of connection structures 200 and at least one semiconductor chip 100 are attached. The preliminary binding reinforcement layer 230P, having a first thickness T1, may conformally cover the first wiring structure 300, to which the plurality of connection structures 200 and at least one semiconductor chip 100 are attached. For example, the first thickness T1 may be about 100 nm to about 3 μm. In some embodiments, the preliminary binding reinforcement layer 230P may be formed by using a silane coupling agent. For example, the preliminary binding reinforcement layer 230P may include silicon nitride oxide (SiON). The preliminary binding reinforcement layer 230P may be formed to cover the upper surface of the first wiring structure 300, the upper side and side surfaces of each of the plurality of connection structures 200, the upper surface of at least one semiconductor chip 100, at least a portion of the side surfaces of the semiconductor chip 100, and the side surfaces of the under-fill layer 150.

Referring to FIG. 2E, a preliminary encapsulation member 250P covering the preliminary binding reinforcement layer 230P may be formed. The preliminary encapsulation member 250P may be formed to include an upper surface at a higher vertical level than the preliminary binding reinforcement layer 230P at the uppermost end, to cover all portions of the preliminary binding reinforcement layer 230P covering the upper surface of each of the plurality of connection structures 200. The preliminary encapsulation member 250P may include a molding member including an epoxy mold compound.

Referring to FIGS. 2E and 2F, by removing a portion of the preliminary encapsulation member 250P and a portion of the preliminary binding reinforcement layer 230P to expose the plurality of connection structures 200, the encapsulation member 250 and the bonding reinforcement layer 230 may be formed. The encapsulation member 250 and the binding reinforcement layer 230 may be formed by removing a portion of the preliminary encapsulation member 250P and a portion of the preliminary binding reinforcement layer 230P by using a chemical mechanical polishing (CMP) process.

The binding reinforcement layer 230 may be formed to cover the upper surface of the first wiring structure 300, the side surfaces of each of the plurality of connection structures 200, the upper surface of at least one semiconductor chip 100, at least a portion of the side surfaces of the semiconductor chip 100, and the side surfaces of the under-fill layer 150. The binding reinforcement layer 230 may not cover the upper surface of the plurality of connection structures 200.

Referring to FIG. 2G, the second wiring structure 400 including the second rewiring insulating layer 410 and the plurality of second rewiring patterns 430, which include the plurality of second rewiring line patterns 432 and the plurality of second rewiring vias 434, may be formed on the binding reinforcement layer 230 and the encapsulation member 250.

After a second preliminary rewiring insulating layer is formed on the plurality of connection structures 200, the binding reinforcement layers 230, and the encapsulation member 250, by removing portions of the second preliminary rewiring insulating layer by using an exposure process and a development process, the second rewiring insulating layer 410 including a plurality of second via holes may be formed. The plurality of second via holes may be formed such that a horizontal width thereof decreases from an upper surface to a lower surface of the second rewiring insulating layer 410. After a second rewiring conductive layer is formed on the second rewiring insulating layer 410, by patterning the second rewiring conductive layer, the second rewiring patterns 430 including the second rewiring line patterns 432 and the second rewiring vias 434 may be formed. The second rewiring patterns 430 formed on the plurality of connection structures 200 may include the plurality of second lower surface connection pads 430P1. The second rewiring vias 434 may include portions filling the plurality of first via holes among the second rewiring patterns 430, and the second rewiring line patterns 432 may include portions above the upper surface of the second rewiring insulating layer 410 among the second rewiring patterns 430. The second rewiring vias 434 may be formed such that a horizontal width thereof decreases from the upper surface to the lower surface of the second rewiring insulating layer 410. Because the second rewiring patterns 430 including the second rewiring line patterns 432 and the second rewiring vias 434 are formed by patterning the second rewiring conductive layer, at least some of the second rewiring line patterns 432 formed on the second rewiring insulating layer 410 including the plurality of second via holes may form one body with at least some of the second rewiring vias 434.

Thereafter, the second rewiring insulating layer 410 and the second rewiring patterns 430 may be repeatedly formed, to form the second wiring structure 400. In some embodiments, the lower surface of the plurality of second lower surface connection pads 430P1 and the lower surface of the second rewiring insulating layer 410 may be formed to be coplanar. In some embodiments, the plurality of second upper surface connection pads 430P2 may be formed to protrude from the upper surface of the second rewiring insulating layer 410 at the uppermost end.

Thereafter, as illustrated in FIG. 1, by attaching the plurality of external connection terminals 500 to the plurality of first lower surface connection pads 330P1, the semiconductor package 1 may be formed.

Referring to FIGS. 1 through 2G, after the preliminary binding reinforcement layer 230P is formed on the plurality of connection structures 200 and the first wiring structure 300, to which at least one semiconductor chip 100 is attached, by forming the preliminary encapsulation member 250P covering the preliminary connection reinforcement layer 230P, and by forming the binding reinforcement layer 230 and the encapsulation member 250 by removing a portion of the preliminary connection reinforcement layer 230P and a portion of the preliminary encapsulation member 250P, the semiconductor package 1 according to the embodiment may be formed.

The binding reinforcement layer 230 may be combined, by using hydrogen binding and sharing binding, with the semiconductor chip 100, the under-fill layer 150, the first rewiring insulating layer 310, the first upper surface connection pad 330P2, the plurality of connection structures 200, and the encapsulation member 250, and thus, the adhesion of the binding reinforcement layer 230 with the semiconductor chip 100, the under-fill layer 150, the first rewiring insulating layer 310, the first upper surface connection pad 330P2, the plurality of connection structures 200, and the encapsulation member 250 may be improved. Accordingly, delamination between the encapsulation member 250 and components adjacent to the encapsulation member 250, for example, delamination between the encapsulation member 250 and each of the semiconductor chip 100, the under-fill layer 150, the first rewiring insulating layer 310, the first upper surface connection pad 330P2, the plurality of connection structures 200 may be prevented, and delamination, which allows moisture causing reliability deterioration, residual ions, or the like to occur, may not be generated internally, and thus, the semiconductor package 1 having improved reliability may be formed.

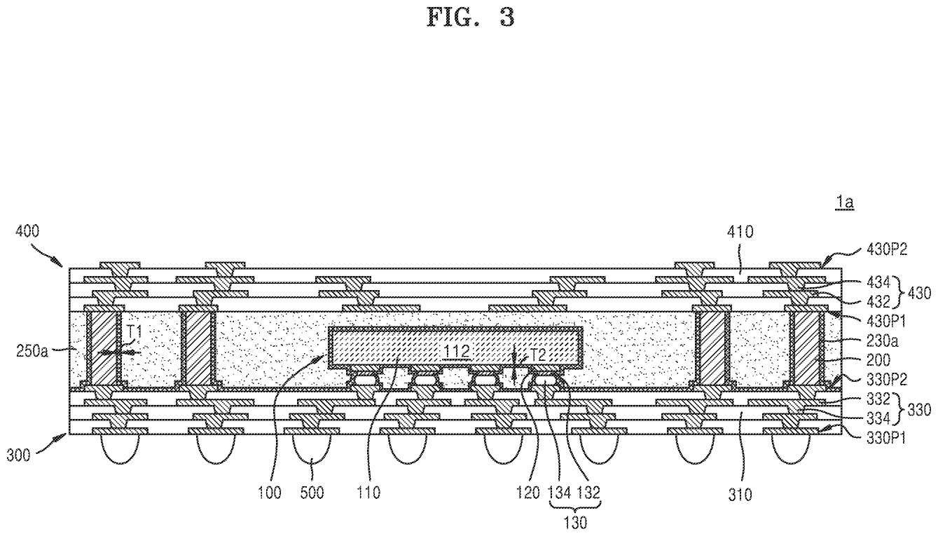

FIG. 3 is a cross-sectional view of a semiconductor package 1a according to an embodiment.

Referring to FIG. 3, the semiconductor package 1a may include a first wiring structure 300, a second wiring structure 400 on the first wiring structure 300, and at least one semiconductor chip 100 arranged between the first wiring structure 300 and the second wiring structure 400. The semiconductor package 1a illustrated in FIG. 3 is largely the same as the semiconductor package 1 illustrated in FIG. 1, except for that the semiconductor package 1a does not include the under-fill layer 150 included in the semiconductor package 1 of FIG. 1, but includes the binding reinforcement layer 230a and an encapsulation member 250a instead of the binding reinforcement layer 230 and the encapsulation member 250 included in the semiconductor package 1 illustrated in FIG. 1, respectively, and thus, duplicated descriptions thereof given with reference to FIG. 1 may be omitted.

The encapsulation member 250a may surround the semiconductor chip 100 on the upper surface of the first wiring structure 300. The encapsulation member 250a may fill a space between the first wiring structure 300 and the second wiring structure 400. The encapsulation member 250a may have a molded under-fill (MUF) structure so that the encapsulation member 250a fills a space between the lower surface of the semiconductor chip 100 and the upper surface of the first wiring structure 300 and surrounds the plurality of chip connection members 130. For example, the encapsulation member 250a may include a molding member including an epoxy mold compound. The encapsulation member 250a may contain a filler.

The binding reinforcement layer 230a may cover the first wiring structure 300, to which the plurality of connection structures 200 and at least one semiconductor chip 100 are attached. The binding reinforcement layer 230a may include an insulating material. In some embodiments, the binding reinforcement layer 230a may include SiON.

The binding reinforcement layer 230a may extend along the side surfaces of the plurality of connection structures 200, the upper surface of the first wiring structure 300, the side surfaces of the plurality of chip connection members 130, and the lower surface, the side surfaces, and the upper surface of at least one semiconductor chip 100.

The first wiring structure 300, to which the plurality of connection structures 200 and at least one semiconductor chip 100 are attached, may be spaced apart from the encapsulation member 250a with the binding reinforcement layer 230a between the first wiring structure 300 and the encapsulation member 250a.

The binding reinforcement layer 230a may cover the side surfaces of each of the plurality of connection structures 200. The binding reinforcement layer 230a may not cover the upper surface of each of the plurality of connection structures 200. The binding reinforcement layer 230a may not cover the lower surface of each of the plurality of connection structures 200.

The binding reinforcement layer 230a may surround at least one semiconductor chip 100. For example, the binding reinforcement layer 230a may cover the upper surface, the side surfaces, and the lower surface of at least one semiconductor chip 100. The binding reinforcement layer 230a may cover the side surfaces of the plurality of chip connection members 130, to surround the plurality of chip connection members 130. The binding reinforcement layer 230a may cover a portion of the side surfaces of the plurality of chip pads 120 protruding from the semiconductor substrate 110 in the vertical direction, and a portion of the lower surface of the plurality of chip pads 120, which are not in contact with the plurality of chip connection members 130. The plurality of chip connection members 130 and the encapsulation member 250a may be spaced apart from each other with the binding reinforcement layer 230a between the plurality of chip connection members 130 and the encapsulation member 250a.

The binding reinforcement layer 230a may cover the upper surface of the first wiring structure 300. For example, the binding reinforcement layer 230a may cover the upper surface of the first rewiring insulating layer 310 at the uppermost end, and a portion of the upper surface and a portion of the side surfaces of the plurality of first upper surface connection pads 330P2. The binding reinforcement layer 230a may not cover the upper surface of the encapsulation member 250.

In some embodiments, a portion of the binding reinforcement layer 230a may have the first thickness T1, and the other portion may have a second thickness T2. The second thickness T2 may be equal to or less than the first thickness T1. A portion of the binding reinforcement layer 230a, which covers the side surfaces of the plurality of connection structures 200, the upper surface and the side surfaces of at least one semiconductor chip 100, and a portion of the upper surface of the first wiring structure 300, may have the first thickness T1. Other portion of the binding reinforcement layer 230a between at least one semiconductor chip 100 and the first wiring structure 300 may have the second thickness T2. For example, a portion of the binding reinforcement layer 230a covering a portion of the lower surface of at least one semiconductor chip 100, a portion of the binding reinforcement layer 230a covering the upper surface of the first wiring structure 300 vertically overlapping at least one semiconductor chip 100, and at least a portion of the binding reinforcement layer 230a surrounding the plurality of chip connection members 130 may have the second thickness T2, that is less than the first thickness T1.

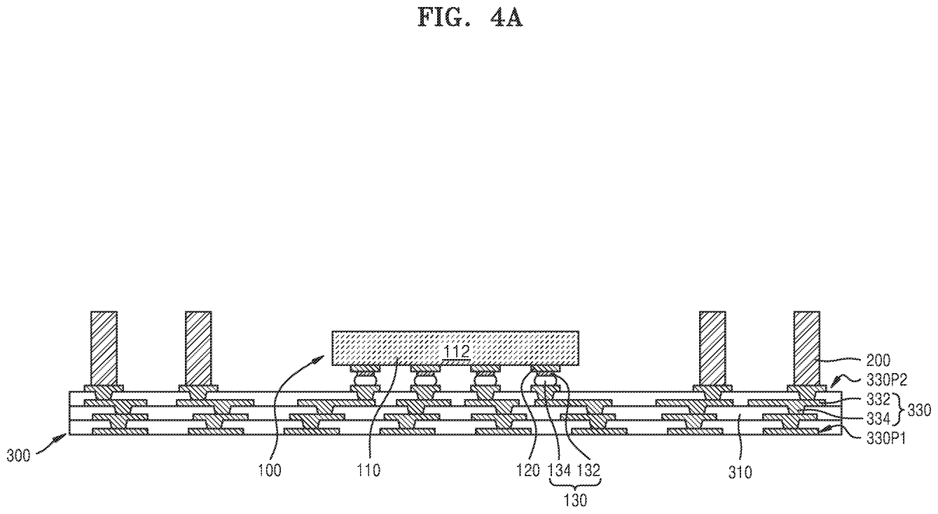

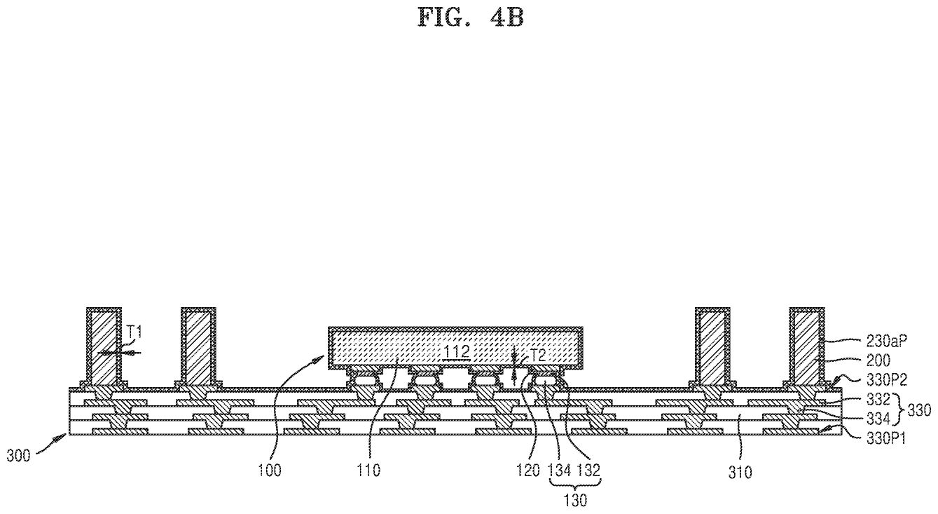

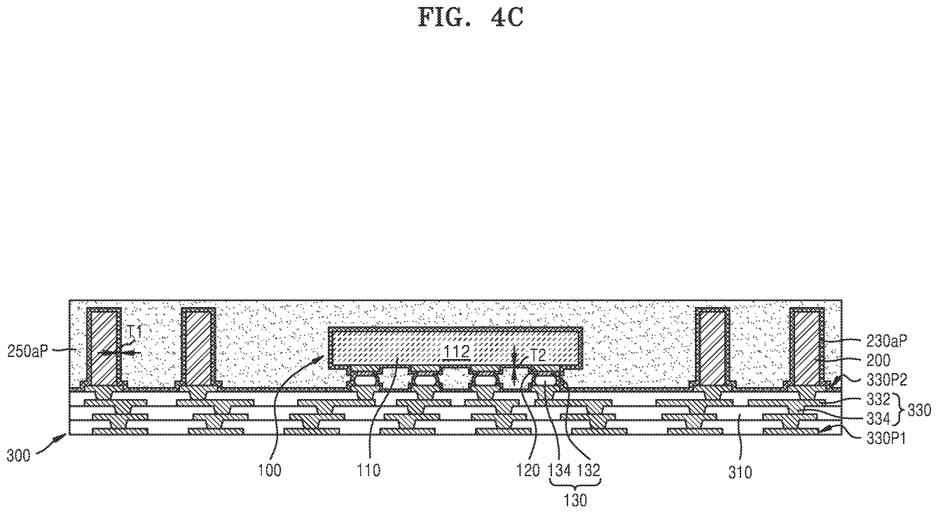

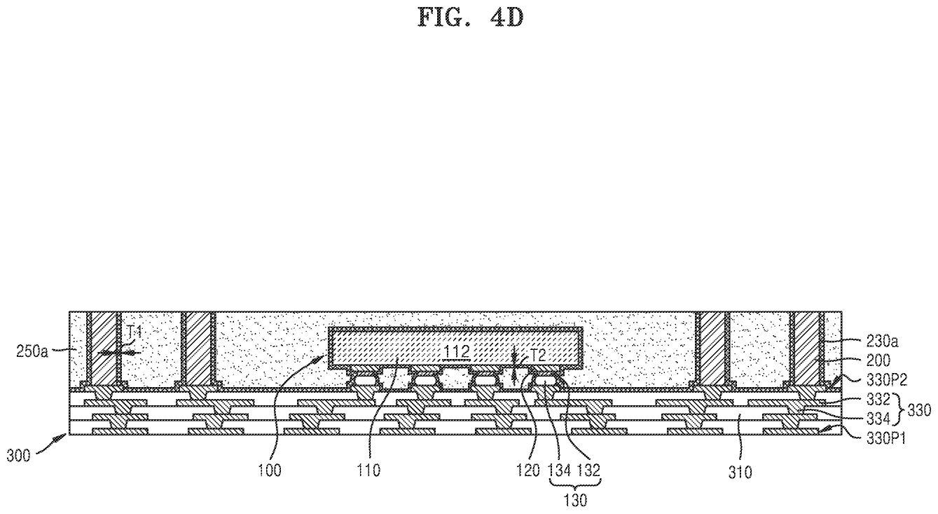

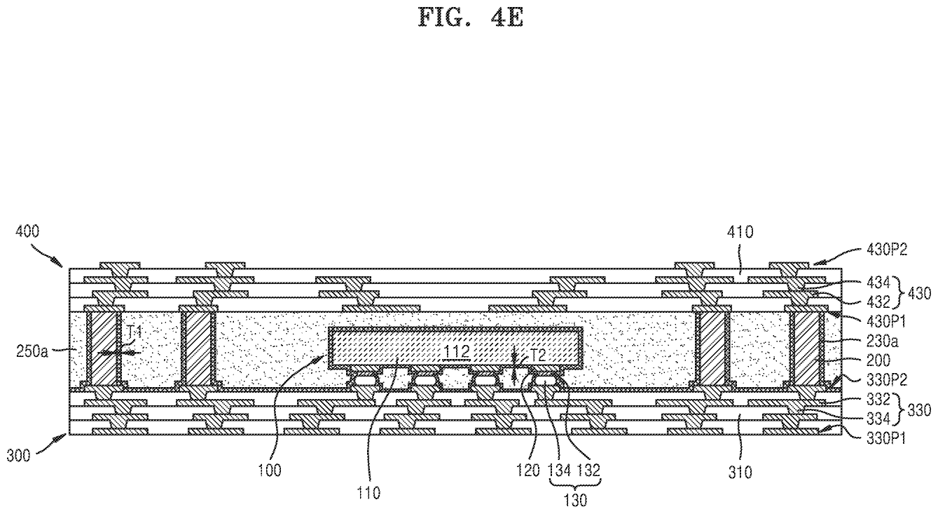

FIGS. 4A through 4E are cross-sectional views illustrating a method of manufacturing the semiconductor package 1a, according to embodiments. FIGS. 4A through 4E are cross-sectional views illustrating a method of manufacturing the semiconductor package 1a illustrated in FIG. 3, and duplicate descriptions thereof given with reference to FIGS. 2A through 2G, and 3 may be omitted.

Referring to FIG. 4A, after the plurality of connection structures 200 are formed on the first wiring structure 300 with reference to FIGS. 2A and 2B, at least one semiconductor chip 100 including the plurality of chip pads 120 may be attached. The semiconductor chip 100 may be attached onto the first wiring structure 300 so that the plurality of chip connection members 130 are arranged between the plurality of chip pads 120 and some of the plurality of first upper surface connection pads 330P2 of the first wiring structure 300.

Referring to FIG. 4B, a preliminary binding reinforcement layer 230aP may be formed on the first wiring structure 300, to which the plurality of connection structures 200 and at least one semiconductor chip 100 are attached. In some embodiments, the preliminary binding reinforcement layer 230aP may be formed by using a silane coupling agent. For example, the preliminary binding reinforcement layer 230aP may include SiON. The preliminary binding reinforcement layer 230aP may be formed to cover the upper surface of the first wiring structure 300, the upper surface and side surfaces of each of the plurality of connection structures 200, the upper surface, the side surfaces, and the lower surface of at least one semiconductor chip 100, and the plurality of chip pads 120. A portion of the binding reinforcement layer 230a may have the first thickness T1, and the other portion of the binding reinforcement layer 203a may have the second thickness T2.

In some embodiments, the first thickness T1 may be equal to the second thickness T2. For example, the preliminary binding reinforcement layer 230aP may conformally cover, with the same thickness, the first wiring structure 300, to which the plurality of connection structures 200 and at least one semiconductor chip 100 are attached.

In some other embodiments, the second thickness T2 may be less than the first thickness T1. For example, when a relatively small amount of silane coupling agent is supplied between at least one semiconductor chip 100 and the first wiring structure 300, the other portion of the binding reinforcement layer 230a arranged between at least one semiconductor chip 100 and the first wiring structure 300 may have a relatively small second thickness T2.

Referring to FIG. 4C, a preliminary encapsulation member 250aP covering the preliminary binding reinforcement layer 230aP may be formed. The preliminary encapsulation member 250aP may be formed to include an upper surface at a higher vertical level than the preliminary binding reinforcement layer 230aP at the uppermost end, to cover all portions of the preliminary binding reinforcement layer 230aP covering the upper surface of each of the plurality of connection structures 200. The preliminary encapsulation member 250aP may include a molding member including an epoxy mold compound.

Referring to FIGS. 4C and 4D, by removing a portion of the preliminary encapsulation member 250aP and a portion of the preliminary binding reinforcement layer 230aP to expose the plurality of connection structures 200, the encapsulation member 250a and the bonding reinforcement layer 230a may be formed. The encapsulation member 250a and the binding reinforcement layer 230a may be formed by removing a portion of the preliminary encapsulation member 250aP and a portion of the preliminary binding reinforcement layer 230aP by using a CMP process.

The binding reinforcement layer 230a may be formed to cover the upper surface of the first wiring structure 300, the side surfaces of each of the plurality of connection structures 200, the upper surface of at least one semiconductor chip 100, at least a portion of the side surfaces of the semiconductor chip 100, and the side surfaces of the under-fill layer 150. The binding reinforcement layer 230a may not cover the upper surface of the plurality of connection structures 200.

Referring to FIG. 4E, the second wiring structure 400 including the second rewiring insulating layer 410 and the plurality of second rewiring patterns 430, which include the plurality of second rewiring line patterns 432 and the plurality of second rewiring vias 434, may be formed on the binding reinforcement layer 230a and the encapsulation member 250a.

Thereafter, as illustrated in FIG. 3, by attaching the plurality of external connection terminals 500 to the plurality of first lower surface connection pads 330P1, the semiconductor package 1a may be formed.

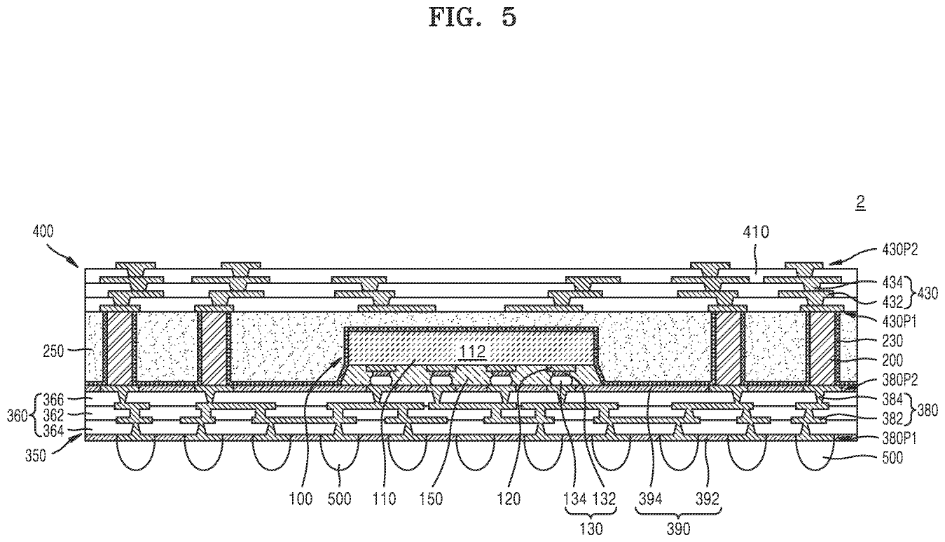

FIG. 5 is a cross-sectional view of a semiconductor package 2 according to an embodiment.

Referring to FIG. 5, the semiconductor package 2 may include a first wiring structure 350, the second wiring structure 400 on the first wiring structure 350, and at least one semiconductor chip 100 arranged between the first wiring structure 350 and the second wiring structure 400. The semiconductor package 2 illustrated in FIG. 5 may be generally the same as the semiconductor package 1 illustrated in FIG. 1, except for that the first wiring structure 350 is included instead of the first wiring structure 300 included in the semiconductor package 1, and thus, duplicate descriptions given with reference to FIG. 1 may be omitted.

The first wiring structure 350 may include a printed circuit board. For example, the first wiring structure 350 may include a double-sided printed circuit board or a multi-layer printed circuit board. When the first wiring structure 350 is a multi-layer printed circuit board, wiring layers may be arranged on the lower surface, the upper surfaces, and the inside of the first wiring structure 350. The first wiring structure 350 may include a plurality of first base insulating layers 360, which are stacked on each other, and a plurality of first wiring patterns 380. A wiring layer may be referred to a portion of the plurality of first wiring patterns 380 arranged at the same vertical level. The wiring layers may be arranged between an upper surface and a lower surface of the first wiring structure 350, and between each of two adjacent first base insulating layers 360 among the plurality of first base insulating layers 360.

Each of the plurality of first base insulating layers 360 may include at least one material of phenol resin, epoxy resin, and polyimide. For example, the plurality of first base insulating layers 360 may include at least one material of frame retardant 4 (FR4), tetrafunctional epoxy, polyphenylene ether, epoxy/polyphenylene oxide, bismaleimide triazine (BT), thermount, cyanate ester, polyimide, and liquid crystal polymer.

The plurality of first base insulating layers 360 may include the core layer 362 and at least one prepreg layer stacked on each of an upper surface and a lower surface of the core layer 362. For example, the plurality of first base insulating layers 360 may include the core layer 362, at least one lower prepreg layer 364 stacked on the lower surface of the core layer 362, and at least one upper prepreg layer 366 stacked on the upper surface of the core layer 362. Each of the core layer 362, the lower prepreg layer 364, and the upper prepreg layer 366 may include the same material. In FIG. 5, one upper prepreg layer 366 is stacked on an upper surface of the core layer 362, and one lower prepreg layer 364 is stacked on a lower surface of the core layer 312, but embodiments are not limited thereto. For example, two or more upper prepreg layers 366 may be stacked sequentially on the upper surface of the core layer 362, and two or more lower prepreg layers 364 may be stacked sequentially on the lower surface of the core layer 362.

In some embodiments, the thickness of each of the upper prepreg layer 366 and the lower prepreg layer 364 may be less than the thickness of the core layer 362. For example, the thickness of the core layer 362 may be about 70 μm to about 1500 μm, and the thickness of each of the upper prepreg layer 366 and the lower prepreg layer 364 may be about 50 μm to about 200 μm.

The plurality of first wiring patterns 380 may include a plurality of first wiring line patterns 382 arranged on an upper surface and a lower surface of each of the plurality of first base insulation layers 360, and a plurality of first wiring vias 384 penetrating at least one first base insulating layer 360 among the plurality of first base insulating layers 360 and electrically connected between the first wiring line patterns 382 respectively arranged on the wiring layers at different vertical levels. The first wiring line patterns 382 at the same vertical level may form one wiring layer.

Each of the plurality of first wiring line patterns 382 may include, for example, electronically deposited (ED) copper foil, rolled-annealed (RA) copper foil, stainless steel foil, aluminum foil, ultra-thin copper foil, sputtered copper, an copper alloy, etc.

The plurality of first wiring line patterns 382 may include a plurality of first lower surface connection pads 380P1 and a plurality of first upper surface connection pads 380P2 arranged on the lower surface and the upper surface of the first wiring structure 350. For example, the plurality of first lower surface connection pads 380P1 may be arranged on the lower surface of the lower prepreg layer 364, which is the first base insulating layer 360 at the lowermost end among the plurality of first base insulating layers 360, and the plurality of first upper surface connection pads 380P2 may be arranged on the upper surface of the upper prepreg layer 366, which is the first base insulating layer 360 at the uppermost end among the plurality of first base insulating layers 360. The plurality of chip connection members 130 may be attached to some of the plurality of first upper surface connection pads 380P2, and a plurality of connection structures 200 may be attached to the others of the plurality of first upper surface connection pads 380P2.

In some embodiments, the first wiring structure 350 may include a solder resist layer 390 arranged on the upper surface and the lower surface of the first wiring structure 350. The solder resist layer 390 may include a lower surface solder resist layer 392 arranged on the lower surface of the first wiring structure 350, and an upper surface solder resist layer 394 arranged on the upper surface of the first wiring structure 350. At least a portion of each of the plurality of first lower surface connection pads 380P1 may not be covered by the lower surface solder resist layer 392, but may be exposed to the lower surface of the first wiring structure 350. At least a portion of each of the plurality of first upper surface connection pads 380P2 may not be covered by the upper surface solder resist layer 394, but may be exposed to the upper surface of the first wiring structure 350.

In some embodiments, the lower surface solder resist layer 392 arranged on the lower surface of the first wiring structure 350 may be formed, but the upper surface solder resist layer 394 arranged on the upper surface of the first wiring structure 350 may not be formed.

In some embodiments, each of the lower surface solder resist layer 392 and the upper surface solder resist layer 394 may be formed by doping solder mask insulating ink on the upper surface and the lower surface of the first base insulating layer 360 by using a screen printing method or an inkjet printing method, and curing the solder mask insulating ink by applying heat, ultraviolet (UV), or infrared (IR). In some other embodiment, each of the first lower surface solder resist layer 392 and the upper surface solder resist layer 394 may be formed by doping a photo-imagable solder resist on the entire area of the upper surface and the lower surface of the first base insulating layer 360 by using a screen printing method or a spray coating method, or by attaching a film-type solder resist material to the entire area thereof by using a laminating method of a film-type solder resist material, and then, by removing unnecessary portions of the entire area thereof by using an exposure process and a development process, and by curing the entire area thereof by using heat, UV, or IR.

In FIG. 5, only the plurality of first upper surface connection pads 380P2 are arranged on the upper surface of the first base insulating layer 360 at the uppermost end among the plurality of first base insulating layers 360, and only the plurality of first lower surface connection pads 380P1 are arranged on the lower surface of the first base insulating layer 360 at the lowermost end, but embodiments are not limited thereto. For example, the first wiring line pattern 382 covered by the lower surface solder resist layer 392 may be arranged on the lower surface of the first base insulating layer 360 at the lowermost end among the plurality of first base insulating layers 360, and the first wiring line pattern 382 covered by the upper surface solder resist layer 394 may be arranged on the upper surface of the first base insulating layer 360 at the uppermost end.

In some embodiments, the plurality of first upper surface connection pads 380P2 and the plurality of first lower surface connection pads 380P1 may be buried in any one of the plurality of first base insulating layers 360. For example, the lower surface of the plurality of first upper surface connection pads 380P2 and the upper surface of the upper prepreg layer 366 of the first base insulating layer 360 at the uppermost end among the plurality of first base insulating layers 360 may be at the same vertical level to be coplanar, and the lower surface of the plurality of first upper surface connection pads 380P1 and the lower surface of the lower prepreg layer 364, which is the first base insulating layer 360 at the lowermost end among the plurality of first base insulating layers 360 may be at the same vertical level to be coplanar.

A plurality of external connection terminals 500 may be respectively attached to the plurality of first lower surface connection pads 380P1. For example, a plurality of external connection terminals 500 may be attached to the lower surfaces of the plurality of first lower surface connection pads 380P1.

A metal layer, unlike other first wiring line patterns 382, may be further formed on the plurality of first upper surface connection pads 380P2 and the plurality of first lower surface connection pads 380P1 among the plurality of first wiring line patterns 382. For example, the metal layer may be arranged on the upper surface of the plurality of first upper surface connection pads 380P2 and on the lower surface of the plurality of first lower surface connection pads 380P1. The metal layer may be formed to improve adhesive force of each of the plurality of first upper surface connection pads 380P2 and the plurality of first lower surface connection pads 380P1, and may reduce contact resistance thereof. For example, the metal layer may be formed by applying a hot air solder leveling (HASL) process, a nickel/gold (Ni/Au) plating process, etc.

Each of the plurality of first wiring vias 384 may electrically connect between two first wiring line patterns 382 arranged on different vertical layers from each other. Each of a plurality of first wiring vias 384 may penetrate at least one first base insulating layer 360. For example, the plurality of first wiring vias 384 may electrically connect between the plurality of first upper surface connection pads 380P2 and the plurality of first lower surface connection pads 380P1. For example, the plurality of first upper surface connection pads 380P2 may be electrically connected to the plurality of first lower surface connection pad 380P1 via at least one first wiring line pattern 382 arranged between two adjacent first base insulating layer 360 among the plurality of first base insulating layers 360 and at least two first wiring vias 384. The plurality of first wiring vias 384 may include, for example, Cu, Ni, stainless steel, or beryllium copper.

At least one semiconductor chip 100 may be attached on the first wiring structure 350. In some embodiments, the semiconductor chip 100 may have a face-down arrangement, in which the plurality of chip pads 120 face the first wiring structure 350, and may be attached to the upper surface of the first wiring structure 350. The plurality of chip connection members 130 may be arranged between the plurality of chip pads 120 of the semiconductor chip 100 and some of the plurality of first upper surface connection pads 380P2 of the first wiring structure 350.

The encapsulation member 250 may surround the semiconductor chip 100 on the upper surface of the first wiring structure 350. The encapsulation member 250 may fill a space between the first wiring structure 350 and the second wiring structure 400. In some embodiment, an under-fill layer 150 surrounding the plurality of chip connection members 130 may be between the semiconductor chip 100 and the first wiring structure 350.

The plurality of connection structures 200 may penetrate the encapsulation member 250, and electrically connect between the first wiring structure 350 and the second wiring structure 400. The plurality of connection structures 200 may be between the plurality of first upper surface connection pads 380P2 and the plurality of second lower surface connection pads 430P1. The encapsulation member 250 may surround the plurality of connection structures 200.

The binding reinforcement layer 230 may cover the first wiring structure 350, to which the plurality of connection structures 200 and at least one semiconductor chip 100 are attached. The binding reinforcement layer 230 may conformally cover the first wiring structure 350, to which the plurality of connection structures 200 and at least one semiconductor chip 100 are attached. The first wiring structure 350, to which the plurality of connection structures 200 and at least one semiconductor chip 100 are attached, may be spaced apart from the encapsulation member 250, with the binding reinforcement layer 230 therebetween. In other words, the binding reinforcement layer 230 may be arranged between the first wiring structure 350, to which the plurality of connection structures 200 and at least one semiconductor chip 100 are attached, and the encapsulation member 250, and may extend along a space the first wiring structure 350 and the encapsulation member 250.

The binding reinforcement layer 230 may cover the upper surface of the first wiring structure 350. For example, the binding reinforcement layer 230 may be arranged between the upper surface of the first wiring structure 350 and the encapsulation member 250. The encapsulation member 250 may contact the binding reinforcement layer 230, but may not contact the first wiring structure 350. The first wiring structure 350 and the encapsulation member 250 may be spaced apart from each other with the binding reinforcement layer 230 therebetween. One of the opposite sides of the binding reinforcement layer 230 may be in direct contact with the upper surface of the first wiring structure 350, and the other of the opposite sides of the binding reinforcement layer 230 may be in direct contact with the encapsulation member 250. For example, the binding reinforcement layer 230 may be in contact with a portion of the upper surface of the plurality of first upper surface connection pads 380P2, and an upper surface of the upper surface solder resist layer 394.

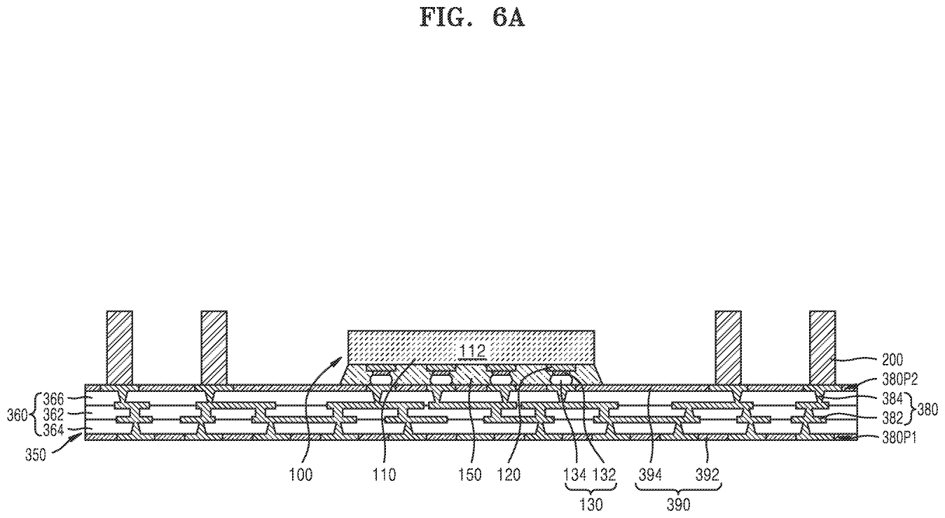

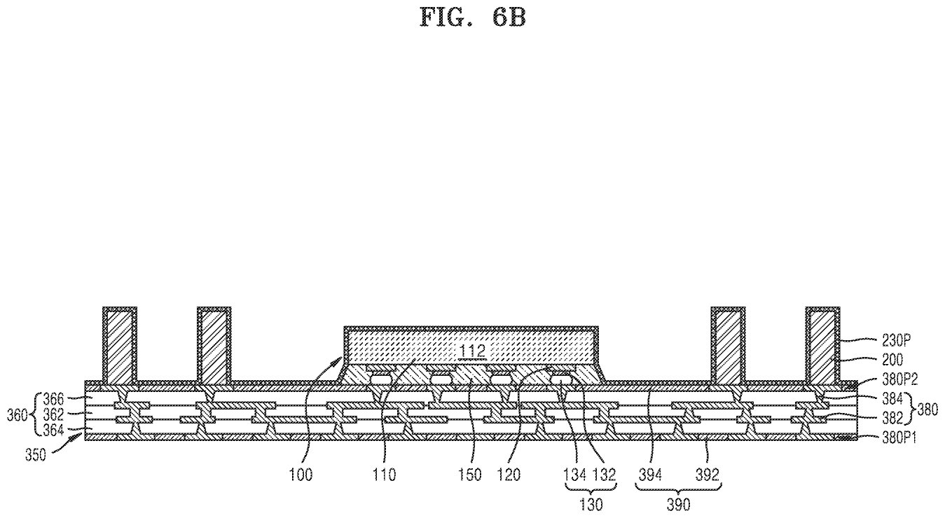

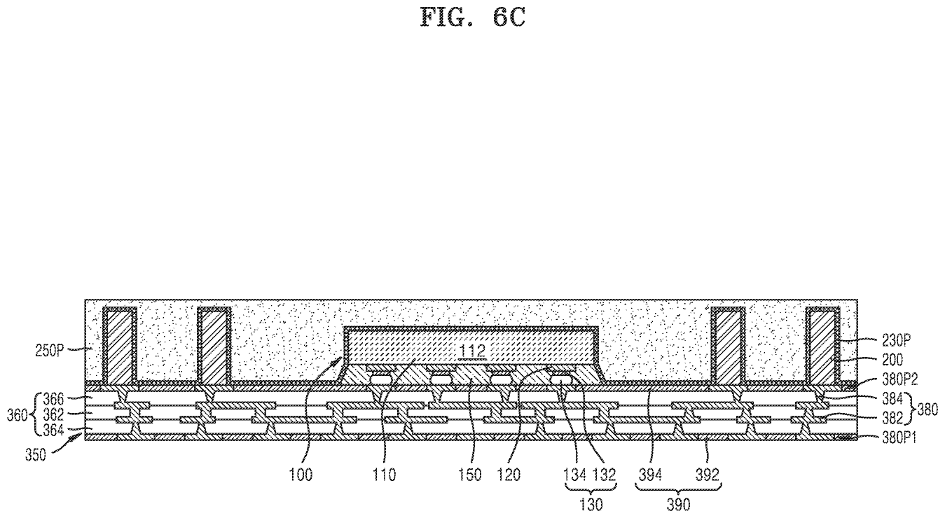

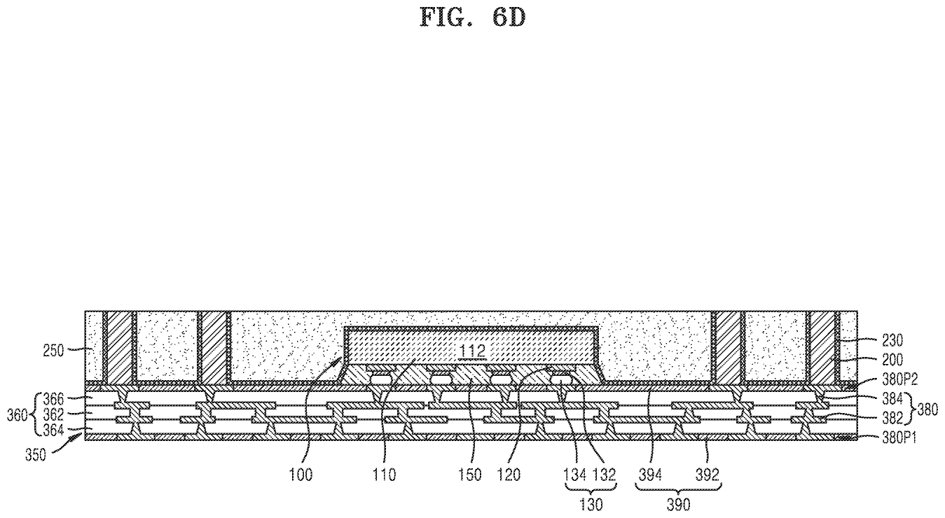

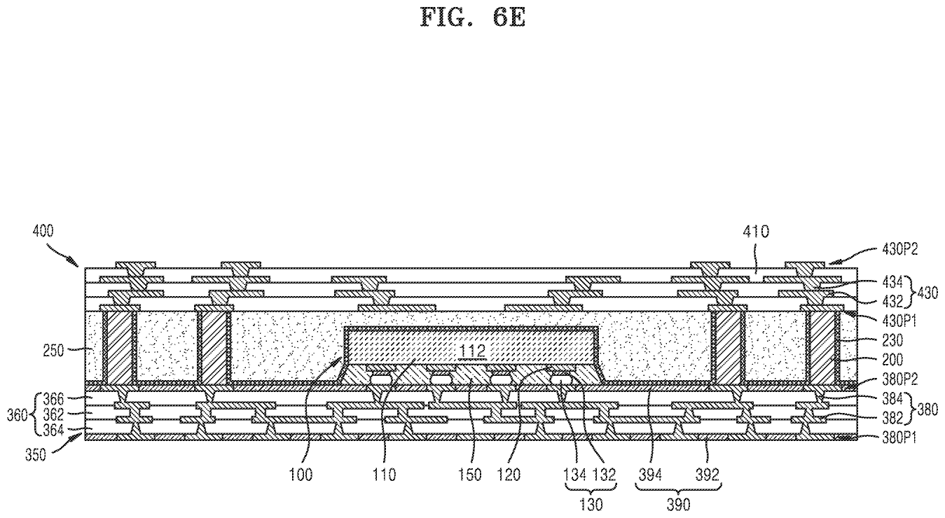

FIGS. 6A through 6E are cross-sectional views illustrating a method of manufacturing the semiconductor package 2, according to embodiments. FIGS. 6A through 6E are cross-sectional views illustrating a method of manufacturing the semiconductor package 2 illustrated in FIG. 5, and duplicate descriptions given with reference to FIG. 5 may be omitted.

Referring to FIG. 6A, after the first wiring structure 350 is prepared, the plurality of connection structures 200 may be formed on some of the plurality of first upper surface connection pads 380P2. In some embodiments, after a mask pattern exposing a portion of each of the plurality of first upper surface connection pads 380P2 is formed on the first wiring structure 350, by performing a plating process on a portion of each of the plurality of first upper surface connection pads 380P2, which is exposed, the plurality of connection structures 200 may be formed. After the plurality of connection structures 200 are formed, the mask pattern may be removed.

Thereafter, at least one semiconductor chip 100 including the plurality of chip pads 120 may be attached onto the first wiring structure 350. The semiconductor chip 100 may be attached onto the first wiring structure 350 so that the plurality of chip connection members 130 are arranged between the plurality of chip pads 120 and some of the plurality of first upper surface connection pads 380P2 of the first wiring structure 350. In some embodiments, after each of the plurality of chip connection members 130 including the UBM layer 132 and the conductive cap 134 covering the UBM layer 132 is formed on the plurality of chip pads 120 of at least one semiconductor chip 100, at least one semiconductor chip 100, in which the plurality of chip connection members 130 are formed, may be attached onto the first wiring structure 350. The under-fill layer 150 may be formed to fill a space between at least one semiconductor chip 100 and the first wiring structure 350.

Referring to FIG. 6B, a preliminary binding reinforcement layer 230P may be formed on the first wiring structure 350, to which the plurality of connection structures 200 and at least one semiconductor chip 100 are attached. The preliminary binding reinforcement layer 230P may be formed to cover the upper surface of the first wiring structure 350, the upper surface and side surfaces of each of the plurality of connection structures 200, the upper surface of at least one semiconductor chip 100, at least a portion of the side surfaces of the semiconductor chip 100, and the side surfaces of the under-fill layer 150.

Referring to FIG. 6C, a preliminary encapsulation member 250P covering the preliminary binding reinforcement layer 230P may be formed. The preliminary encapsulation member 250P may be formed to include an upper surface at a higher vertical level than the preliminary binding reinforcement layer 230P at the uppermost end, to cover all portions of the preliminary binding reinforcement layer 230P covering the upper surface of each of the plurality of connection structures 200.

Referring to FIGS. 6C and 6D, by removing a portion of the preliminary encapsulation member 250P and a portion of the preliminary binding reinforcement layer 230P to expose the plurality of connection structures 200, the encapsulation member 250 and the bonding reinforcement layer 230 may be formed.

The binding reinforcement layer 230 may be formed to cover the upper surface of the first wiring structure 350, the side surfaces of each of the plurality of connection structures 200, the upper surface of at least one semiconductor chip 100, at least a portion of the side surfaces of the semiconductor chip 100, and the side surfaces of the under-fill layer 150. The binding reinforcement layer 230 may not cover the upper surface of the plurality of connection structures 200.

Referring to FIG. 6E, the second wiring structure 400 including the second rewiring insulating layer 410 and the plurality of second rewiring patterns 430, which include the plurality of second rewiring line patterns 432 and the plurality of second rewiring vias 434, may be formed on the binding reinforcement layer 230 and the encapsulation member 250.

Thereafter, as illustrated in FIG. 5, by attaching the plurality of external connection terminals 500 to the plurality of first lower surface connection pads 380P1, the semiconductor package 2 may be formed.

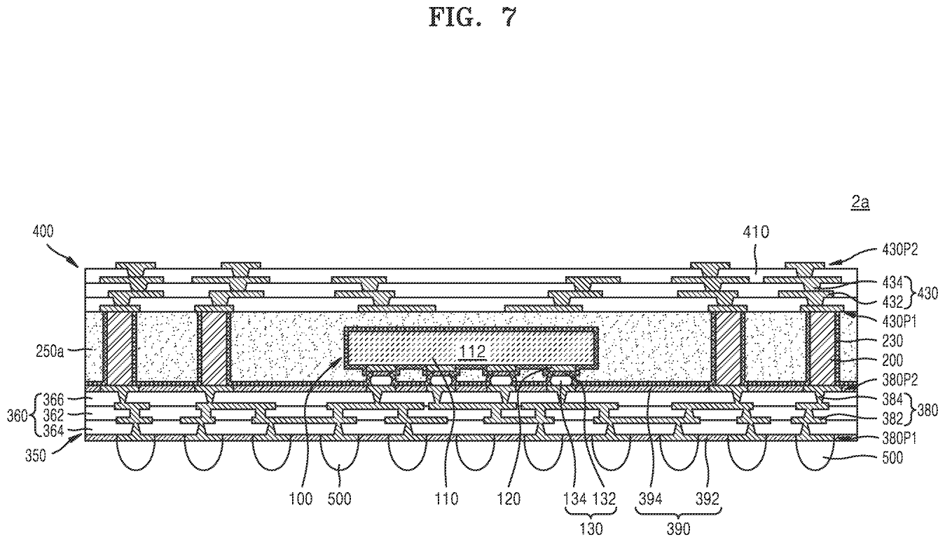

FIG. 7 is a cross-sectional view of a semiconductor package 2a according to an embodiment.

Referring to FIG. 7, the semiconductor package 2a may include a first wiring structure 350, the second wiring structure 400 on the first wiring structure 350, and at least one semiconductor chip 100 arranged between the first wiring structure 350 and the second wiring structure 400. The semiconductor package 2a illustrated in FIG. 7 may be generally the same as the semiconductor package 2a illustrated in FIG. 3, except for that the first wiring structure 350 is included instead of the first wiring structure 300 included in the semiconductor package 1a, and thus, duplicate descriptions given with reference to FIGS. 3 and 6 may be omitted.

The encapsulation member 250a may surround the semiconductor chip 100 on the upper surface of the first wiring structure 350. The encapsulation member 250a may fill a space between the first wiring structure 350 and the second wiring structure 400. The encapsulation member 250a may have an MUF structure so that the encapsulation member 250a fills a space between the lower surface of the semiconductor chip 100 and the upper surface of the first wiring structure 350 and surrounds the plurality of chip connection members 130.

The binding reinforcement layer 230a may cover the first wiring structure 350, to which the plurality of connection structures 200 and at least one semiconductor chip 100 are attached.

The first wiring structure 350, to which the plurality of connection structures 200 and at least one semiconductor chip 100 are attached, may be spaced apart from the encapsulation member 250a with the binding reinforcement layer 230a between the first wiring structure 350 and the encapsulation member 250a. For example, the binding reinforcement layer 230a may be arranged between the first wiring structure 350, to which the plurality of connection structures 200 and at least one semiconductor chip 100 are attached, and the encapsulation member 250a, and may extend along a space between the first wiring structure 350 and the encapsulation member 250a.

The binding reinforcement layer 230a may cover the side surfaces of each of the plurality of connection structures 200. The binding reinforcement layer 230a may not cover the upper surface of each of the plurality of connection structures 200. The binding reinforcement layer 230a may not cover the lower surface of each of the plurality of connection structures 200.

The binding reinforcement layer 230a may surround at least one semiconductor chip 100. For example, the binding reinforcement layer 230a may cover the upper surface, the side surfaces, and the lower surface of at least one semiconductor chip 100. The binding reinforcement layer 230a may surround the plurality of chip connection members 130. The binding reinforcement layer 230a may cover a portion of the side surfaces of the plurality of chip pads 120 protruding from the semiconductor substrate 110 in the vertical direction, and a portion of the lower surface of the plurality of chip pads 120, which are not in contact with the plurality of chip connection members 130. The plurality of chip connection members 130 and the encapsulation member 250a may be spaced apart from each other with the binding reinforcement layer 230a therebetween.

The binding reinforcement layer 230a may cover the upper surface of the first wiring structure 350. For example, the binding reinforcement layer 230a may be in contact with a portion of the upper surface of the plurality of first upper surface connection pads 380P2, and an upper surface of the upper surface solder resist layer 394.

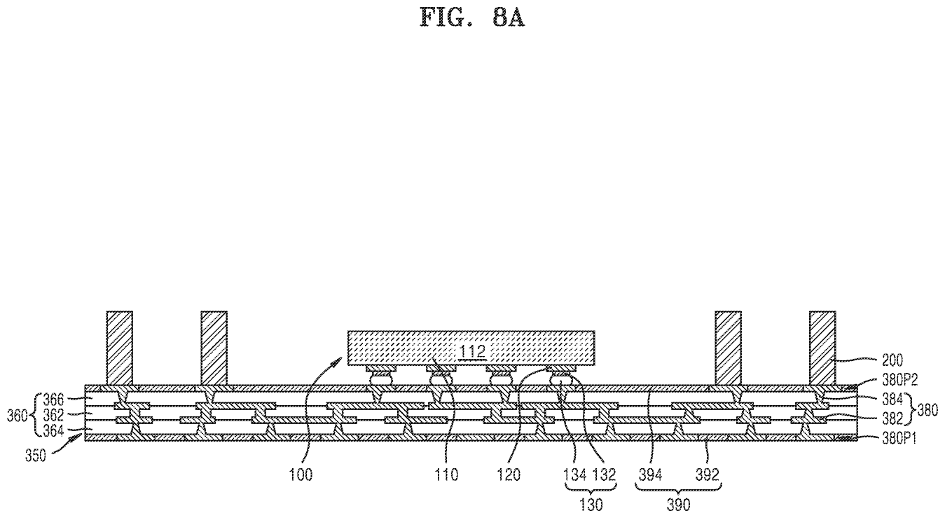

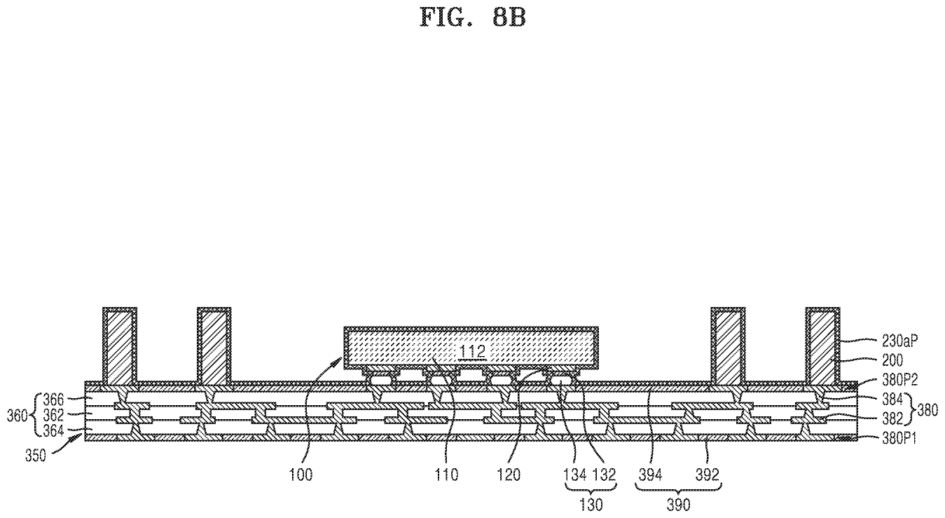

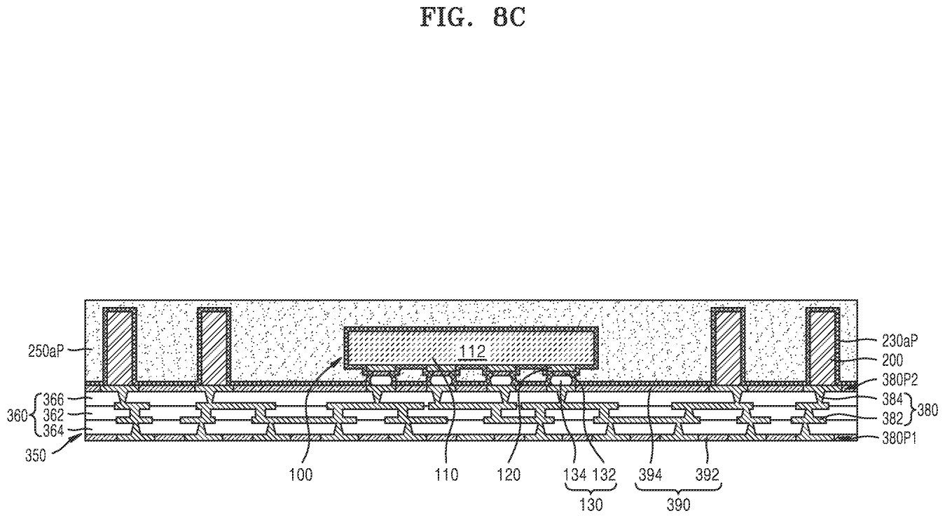

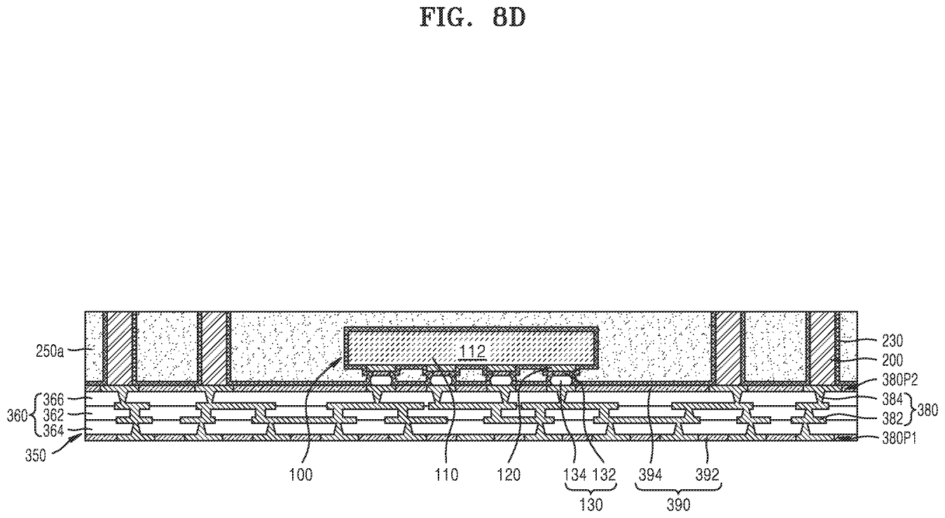

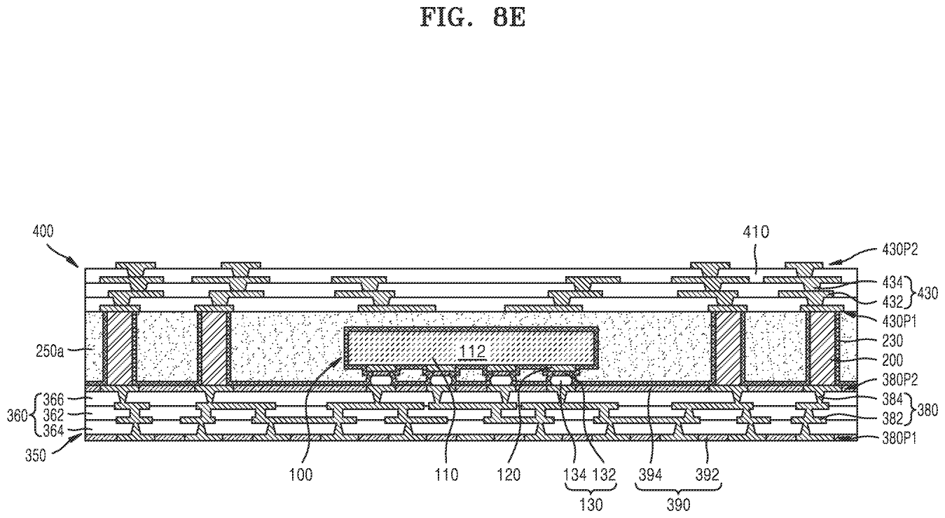

FIGS. 8A through 8E are enlarged cross-sectional views illustrating a method of manufacturing the semiconductor package 2a, according to embodiments. FIGS. 8A through 8E are cross-sectional views illustrating a method of manufacturing the semiconductor package 2a illustrated in FIG. 7, and duplicate descriptions thereof given with reference to FIGS. 6A through 6E, and 5 may be omitted.

Referring to FIG. 8A, after the plurality of connection structures 200 is formed on the first wiring structure 350, at least one semiconductor chip 100 including the plurality of chip pads 120 may be attached.

Referring to FIG. 8B, a preliminary binding reinforcement layer 230aP may be formed on the first wiring structure 350, to which the plurality of connection structures 200 and at least one semiconductor chip 100 are attached. The preliminary binding reinforcement layer 230aP may be formed to cover the upper surface of the first wiring structure 350, the upper surface and side surfaces of each of the plurality of connection structures 200, the upper surface, the side surfaces, and the lower surface of at least one semiconductor chip 100, and the plurality of chip pads 120.

Referring to FIG. 8C, a preliminary encapsulation member 250aP covering the preliminary binding reinforcement layer 230aP may be formed. The preliminary encapsulation member 250aP may be formed to include an upper surface at a higher vertical level than the preliminary binding reinforcement layer 230aP at the uppermost end, to cover all portions of the preliminary binding reinforcement layer 230aP covering the upper surface of each of the plurality of connection structures 200.

Referring to FIGS. 8C and 8D, by removing a portion of the preliminary encapsulation member 250aP and a portion of the preliminary binding reinforcement layer 230aP to expose the plurality of connection structures 200, the encapsulation member 250a and the bonding reinforcement layer 230a may be formed.

The binding reinforcement layer 230a may be formed to cover the upper surface of the first wiring structure 300, the side surfaces of each of the plurality of connection structures 200, the upper surface of at least one semiconductor chip 100, at least a portion of the side surfaces of the semiconductor chip 100, and the side surfaces of the under-fill layer 150. The binding reinforcement layer 230a may not cover the upper surface of the plurality of connection structures 200.

Referring to FIG. 8E, the second wiring structure 400 including the second rewiring insulating layer 410 and the plurality of second rewiring patterns 430, which include the plurality of second rewiring line patterns 432 and the plurality of second rewiring vias 434, may be formed on the binding reinforcement layer 230a and the encapsulation member 250a.

Thereafter, as illustrated in FIG. 7, by attaching the plurality of external connection terminals 500 to the plurality of first lower surface connection pads 380P1, the semiconductor package 2a may be formed.

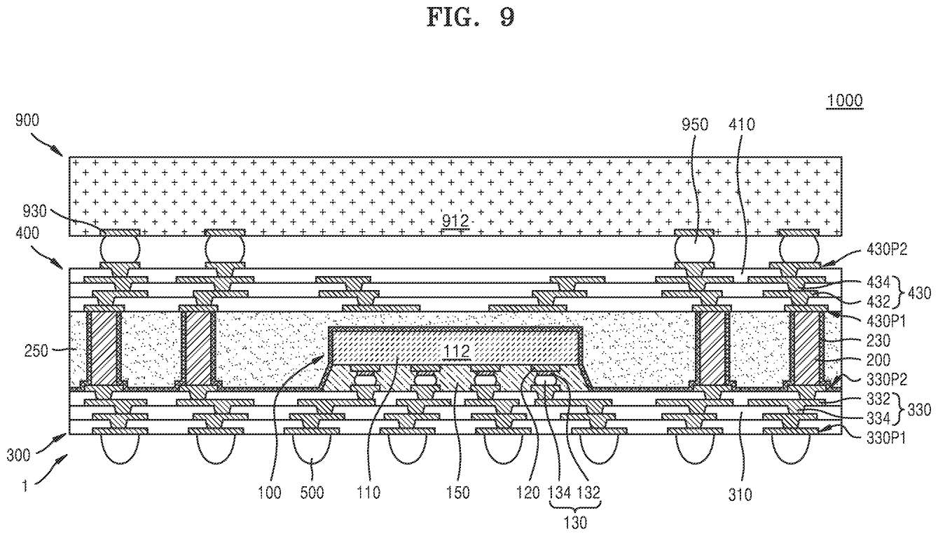

FIGS. 9 through 12 are cross-sectional views of a semiconductor package 1000 according to embodiments.

Referring to FIG. 9, the semiconductor package 1000 may include a lower package 1 and an upper package 900 attached onto the lower package 1. The semiconductor package 1000 may include a PoP. The lower package 1 may include the semiconductor package 1 illustrated in FIG. 1.

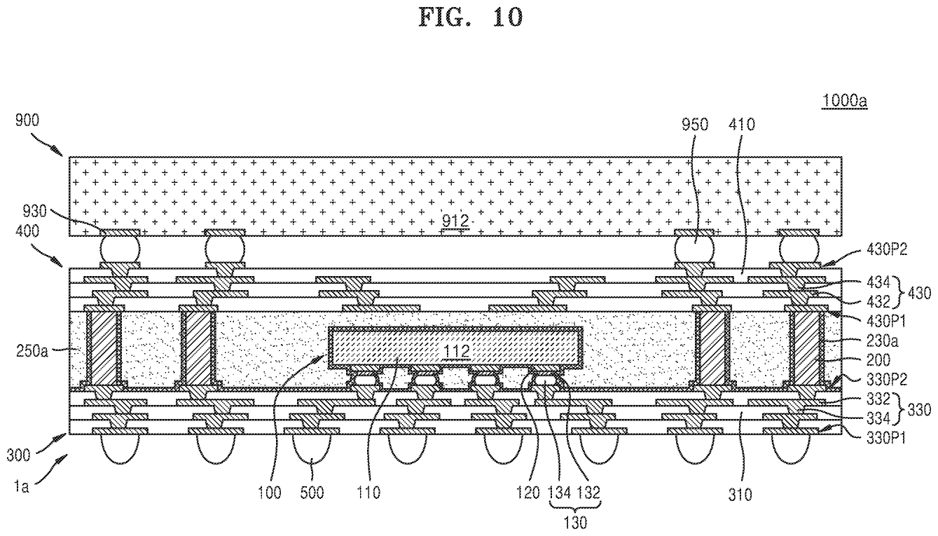

Referring to FIG. 10, a semiconductor package 1000a may include a lower package 1a and an upper package 900 attached onto the lower package 1a. The semiconductor package 1000a may be a PoP. The lower package 1a may include the semiconductor package 1a illustrated in FIG. 3.

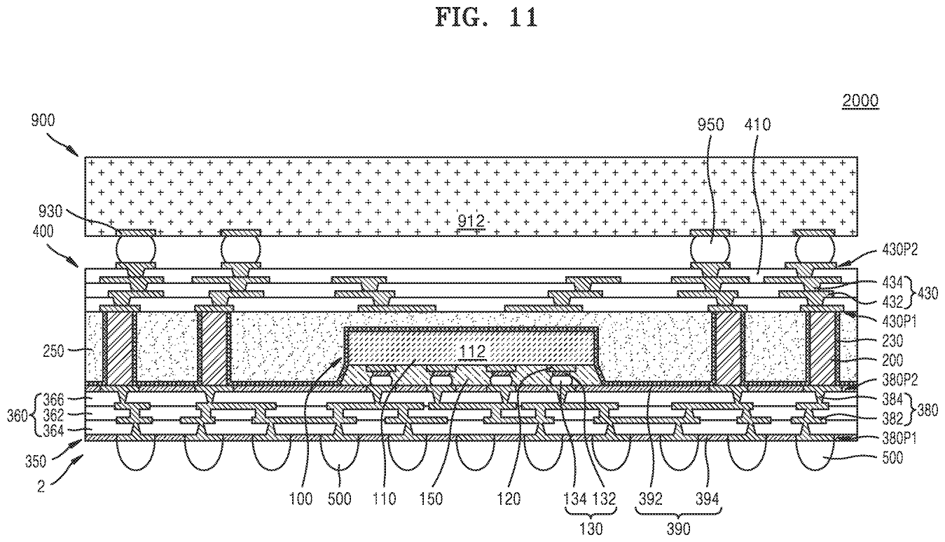

Referring to FIG. 11, a semiconductor package 2000 may include a lower package 2 and the upper package 900 attached onto the lower package 2. The semiconductor package 2000 may include a PoP. The lower package 2 may include the semiconductor package 2 illustrated in FIG. 5.

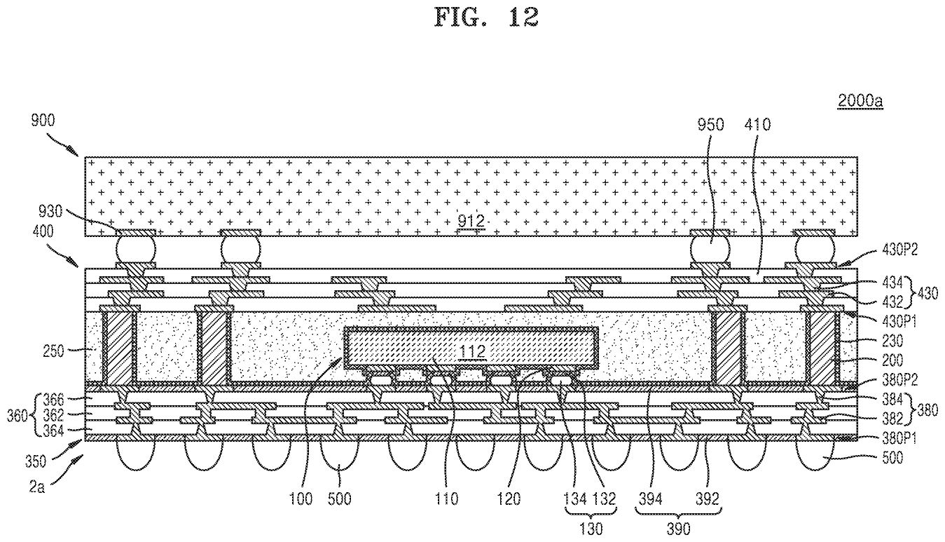

Referring to FIG. 12, a semiconductor package 2000 may include a lower package 2a and the upper package 900 attached onto the lower package 2a. The semiconductor package 2000a may include a PoP. The lower package 2a may include the semiconductor package 2a illustrated in FIG. 7.

Referring to FIGS. 9 through 12 together, the upper package 900 may include an upper semiconductor chip including an upper semiconductor device 912 and a plurality of upper connection pads 930. The upper package 900 may be electrically connected to the lower packages 1, 1a, 2, and 2a via a plurality of package connection terminals 950 arranged between the plurality of upper connection pads 930 and the plurality of second upper surface connection pads 430P2. The upper package 900 may be attached onto the lower packages 1, 1a, 2, and 2a so that the plurality of upper connection pads 930 face the lower packages 1, 1a, 2, and 2a. For example, the upper package 900 may be electrically connected to the plurality of first rewiring patterns 330 of the first wiring structure 300 or the plurality of first wiring patterns 380 of the first wiring structure 350 via the plurality of package connection terminals 950 attached to the plurality of upper connection pads 930, the plurality of second rewiring patterns 430, and the plurality of connection structures 200. In some embodiments, the upper semiconductor device 912 may include a memory device, and the upper semiconductor chip may include a memory semiconductor chip. For example, the memory device may include a non-volatile memory device, such as a flash memory, PRAM, MRAM, FeRAM, and RRAM. The flash memory, in some embodiments, may include a volatile memory device, such as DRAM and SRAM.

The upper package 900 may include one or a plurality of upper semiconductor chips. The upper semiconductor chip may also be mounted in the upper package 900 in a flip chip manner, or may also be electrically connected thereto via a bonding wire and mounted thereon by using a die attach film (DAF). The upper package 900 may also include a plurality of upper semiconductor chips apart from each other in the horizontal direction, and may also include a plurality of upper semiconductor chips stacked in the vertical direction. Alternatively, the upper package 900 may include a plurality of upper semiconductor chips electrically connected each other via through an electrode, and stacked in the vertical direction. Alternatively, the upper package 900 may also include one semiconductor chip.

In other words, the upper package 900 may include at least one upper semiconductor chip including the upper semiconductor device 912, and may correspond to any type of a semiconductor package including the plurality of upper connection pads 930 on the lower side of the upper package 900 to be electrically connected to the lower packages 1, 1a, and 2a.

While the present disclosure has been particularly shown and described with reference to embodiments thereof, it will be understood that various changes in form and details may be made therein without departing from the spirit and scope of the following claims.

What is claimed is:

1. A semiconductor package comprising:
a first wiring structure comprising:
a plurality of first wiring patterns respectively comprising a plurality of first lower surface connection pads and a plurality of first upper surface connection pads; and
a first base insulating layer surrounding the plurality of first wiring patterns;
a second wiring structure comprising:
a plurality of second wiring patterns respectively comprising a plurality of second lower surface connection pads and a plurality of second upper surface connection pads; and
a second base insulating layer surrounding the plurality of second wiring patterns;
a semiconductor chip between the first wiring structure and the second wiring structure;
an encapsulation member filling a space between the first wiring structure and the second wiring structure and surrounding the semiconductor chip;
a plurality of connection structures penetrating the encapsulation member and connecting some of the plurality of first upper surface connection pads to the plurality of second lower surface connection pads, the plurality of connection structures being adjacent to the semiconductor chip; and
a binding reinforcement layer on side surfaces of each of the plurality of connection structures and at least a portion of side surfaces of the semiconductor chip.

2. The semiconductor package of claim 1, wherein the encapsulation member is spaced apart from the semiconductor chip and each of the plurality of connection structures.

3. The semiconductor package of claim 1, wherein the binding reinforcement layer is between the first wiring structure and the encapsulation member, between the semiconductor chip and the encapsulation member, and between the plurality of connection structures and the encapsulation member.

4. The semiconductor package of claim 1, wherein the encapsulation member is spaced apart from the first base insulating layer and is in contact with the second base insulating layer, and
wherein the binding reinforcement layer is between the encapsulation member and the first base insulating layer.

5. The semiconductor package of claim 1, wherein the semiconductor chip comprises:
a plurality of chip pads; and
a plurality of chip connection members between the plurality of chip pads and some of the plurality of first upper surface connection pads.

6. The semiconductor package of claim 5, further comprising an under-fill layer between the semiconductor chip and the first wiring structure, and the under-fill layer surrounding the plurality of chip connection members,
wherein the binding reinforcement layer is on side surfaces of the plurality of connection structures, an upper surface of the first wiring structure, side surfaces of the under-fill layer, side surfaces of the semiconductor chip, and an upper surface of the semiconductor chip.

7. The semiconductor package of claim 5, wherein the binding reinforcement layer is on an upper surface, side surfaces, and a lower surface of the semiconductor chip, the binding reinforcement layer surrounding the plurality of chip connection members, and
wherein the encapsulation member fills a space between the semiconductor chip and the first wiring structure.

8. The semiconductor package of claim 7, wherein portions of the binding reinforcement layer, on side surfaces of the plurality of connection structures, and an upper surface and side surfaces of the semiconductor chip, has a first thickness, and
wherein, at least a portion of the binding reinforcement layer on a lower surface of the semiconductor chip and portions of the binding reinforcement layer surrounding the plurality of chip connection members has a second thickness less than the first thickness.

9. The semiconductor package of claim 1, wherein each of the first wiring structure and the second wiring structure comprises a rewiring structure.

10. The semiconductor package of claim 1, wherein the first wiring structure comprises a printed circuit board, and
wherein the second wiring structure comprises a rewiring structure.

11. A semiconductor package comprising:
a first wiring structure comprising:
a plurality of first rewiring patterns respectively comprising a plurality of first lower surface connection pads and a plurality of first upper surface connection pads; and
a first rewiring insulating layer surrounding the plurality of first rewiring patterns;
a second wiring structure comprising:
a plurality of second rewiring patterns respectively comprising a plurality of second lower surface connection pads and a plurality of second upper surface connection pads; and
a second rewiring insulating layer surrounding the plurality of second rewiring patterns;
a semiconductor chip between the first wiring structure and the second wiring structure, the semiconductor chip comprising a plurality of chip pads;
a plurality of connection structures respectively connecting the plurality of first upper surface connection pads to the plurality of second lower surface connection pads, the plurality of connection structures being adjacent to the semiconductor chip;
a binding reinforcement layer on side surfaces of each of the plurality of connection structures and at least a portion of the semiconductor chip;
a plurality of chip connection members between some of the plurality of first upper surface connection pads and the plurality of chip pads; and
an encapsulation member surrounding the plurality of connection structures and the semiconductor chip, filling a space between the first wiring structure and the second wiring structure, and being spaced apart from the semiconductor chip and each of the plurality of connection structures, the binding reinforcement layer being between the encapsulation member and each of the plurality of connection structures.

12. The semiconductor package of claim 11, wherein the binding reinforcement layer is on an upper surface of the first wiring structure, upper surfaces of the plurality of connection structures, at least a portion of side surfaces of the semiconductor chip, and an upper surface of the semiconductor chip.

13. The semiconductor package of claim 11, further comprising an under-fill layer between the semiconductor chip and the first wiring structure, the under-fill layer surrounding the plurality of chip connection members,
wherein the binding reinforcement layer is on side surfaces of the plurality of connection structures, an upper surface of the first wiring structure, side surfaces of the under-fill layer, at least a portion of side surfaces of the semiconductor chip, and an upper surface of the semiconductor chip.

14. The semiconductor package of claim 11, wherein the binding reinforcement layer is on side surfaces of the plurality of connection structures, an upper surface of the first wiring structure, side surfaces of the plurality of chip connection members, a lower surface of the semiconductor chip, side surfaces of the semiconductor chip, and an upper surface of the semiconductor chip.

15. The semiconductor package of claim 11, wherein the plurality of first upper surface connection pads protrude from an upper surface of the first rewiring insulating layer, and
wherein a lower surface of each of the plurality of second lower surface connection pads and a lower surface of the second rewiring insulating layer are coplanar.

16. The semiconductor package of claim 15, wherein the binding reinforcement layer is on the upper surface of the first rewiring insulating layer, a portion of side surfaces of the plurality of first upper surface connection pads protruding from the upper surface of the first rewiring insulating layer, a portion of the upper surface of the plurality of first upper surface connection pads, the portion of the upper surface not being in contact with the plurality of connection structures, and side surfaces of the plurality of connection structures.

17. The semiconductor package of claim 15, wherein the encapsulation member is spaced apart from the upper surface of the first rewiring insulating layer with the binding reinforcement layer between the encapsulation member and the first rewiring insulating layer, and
wherein the encapsulation member is in contact with the second rewiring insulating layer.

18. A semiconductor package comprising:
a first rewiring structure comprising:
a plurality of first rewiring patterns respectively comprising a plurality of first lower surface connection pads and a plurality of first upper surface connection pads; and
a first rewiring insulating layer surrounding the plurality of first rewiring patterns;
a semiconductor chip on the first rewiring structure and comprising a plurality of chip pads;
a second rewiring structure comprising:
a plurality of second rewiring patterns on the semiconductor chip and the first rewiring structure, the plurality of second rewiring patterns respectively comprising a plurality of second lower surface connection pads and a plurality of second upper surface connection pads; and
a second rewiring insulating layer surrounding the plurality of second rewiring patterns;
a plurality of connection structures respectively connecting some of the plurality of first upper surface connection pads to the plurality of second lower surface connection pads, the plurality of connection structures being on the semiconductor chip; and
a plurality of chip connection members between some of the plurality of first upper surface connection pads and the plurality of chip pads, the plurality of chip connection members respectively comprising a under bump metal (UBM) layer and a conductive cap on each of the plurality of chip pads, the conductive cap covering the UBM layer;
an under-fill layer between the semiconductor chip and the first rewiring structure, the under-fill layer surrounding the plurality of chip connection members,
a binding reinforcement layer on an upper surface of the first rewiring structure, side surfaces of each of the plurality of connection structures, side surfaces of the under-fill layer, at least a portion of side surfaces of the semiconductor chip, and an upper surface of the semiconductor chip, the binding reinforcement layer comprising an insulating material; and
an encapsulation member filling a space between the first rewiring structure and the second rewiring structure, covering the plurality of connection structures and the semiconductor chip, and being spaced apart from the first rewiring structure, the semiconductor chip, and each of the plurality of connection structures, with the binding reinforcement layer between the encapsulation member and the first rewiring structure, the semiconductor chip, and each of the plurality of connection structures.

19. The semiconductor package of claim 18, wherein the binding reinforcement layer comprises silicon oxynitride (SiON).

20. The semiconductor package of claim 18, wherein a thickness of the binding reinforcement layer is 100 nm to 3 μm.
